(19) United States
(12) Patent Application Publication
(10) Pub. No.: US 2026/0047289 A1
(43) Pub. Date: Feb. 12, 2026

(54) DISPLAY PANEL, DISPLAY MODULE, AND ELECTRONIC DEVICE

(71) Applicant: Samsung Display Co., Ltd., Yongin-si (KR)

(72) Inventors: Youngmin AHN, Yongin-si (KR); Hanbum KWON, Yongin-si (KR); Eunbyul KIM, Yongin-si (KR)

(73) Assignee: Samsung Display Co., Ltd., Yongin-si (KR)

(21) Appl. No.: 19/295,913

(22) Filed: Aug. 11, 2025

(30) Foreign Application Priority Data
Aug. 12, 2024 (KR) 10-2024-0107506

(51) Int. Cl. H10K 59/131; H10K 59/95

(52) U.S. Cl. CPC H10K 59/131; H10K 59/95

(57) ABSTRACT

A display panel includes a display area including a pixel, and a non-display area including a pad area, and being adjacent to the display area. A signal pad connected to the pixel through a signal line is disposed in the pad area. The signal pad includes a first pad insulation layer, a first conductive pattern, a second conductive pattern, a second pad insulation layer, a third conductive pattern, a third pad insulation layer, a fourth conductive pattern, and at least one insulation pattern.

### CROSS-REFERENCE TO RELATED APPLICATION(S)

This application claims priority to and the benefits of Korean Patent Application No. 10-2024-0107506 under 35 U.S.C. § 119, filed Aug. 12, 2024, in the Korean Intellectual Property Office (KIPO), the entire contents of which are incorporated herein by reference.

### BACKGROUND

### 1. Technical Field

Embodiments of the disclosure described herein relate to a display panel including a pad area, a display module including the same, and an electronic device.

### 2. Description of the Related Art

Multimedia electronic devices, such as a television, a mobile phone, a tablet, a navigation system, and a game console, may include a display module that displays an image and senses an external input.

The display module may be bonded to a data driver that provides an electrical signal for displaying an image to be electrically connected thereto.

### SUMMARY

Embodiments of the disclosure provide a display panel having an improved bonding reliability, a display module, and an electronic device.

According to an embodiment, a display panel may include a display area including a pixel, and a non-display area including a pad area, and being adjacent to the display area. A signal pad connected to the pixel through a signal line may be disposed in the pad area. The signal pad may include a first pad insulation layer disposed on a distal end of the signal line, and including a first contact hole exposing a portion of the distal end of the signal line, a first conductive pattern disposed on the first pad insulation layer, and connected to the distal end of the signal line through the first contact hole, a second conductive pattern disposed on the first conductive pattern, a second pad insulation layer disposed on the second conductive pattern, and including a second contact hole exposing a portion of the second conductive pattern, a third conductive pattern disposed on the second pad insulation layer, and connected to the second conductive pattern through the second contact hole, a third pad insulation layer disposed on the third conductive pattern, and including a third contact hole exposing a portion of the third conductive pattern, a fourth conductive pattern disposed on the third pad insulation layer, and connected to the third conductive pattern through the third contact hole, and at least one insulation pattern disposed between the third conductive pattern and the fourth conductive pattern.

The display area may include a base layer, a circuit element layer disposed on the base layer, and a light emitting element layer including a light emitting element and disposed on the circuit element layer. The circuit element layer may include a transistor, a first connection electrode connected to the transistor, and a second connection electrode connected to the first connection electrode and the light emitting element. The first conductive pattern and the first connection electrode may be disposed at a same layer, and the second conductive pattern and the second connection electrode may be disposed at a same layer.

The transistor may include a semiconductor pattern including a channel, a source, and a drain, and a gate electrode, the gate electrode and the transistor being disposed at different layers. the first connection electrode may be connected to the source or the drain.

The light emitting element may include a first electrode, a light emission layer disposed on the first electrode, and a second electrode disposed on the light emission layer, and the second connection electrode may be connected to the first electrode.

The first conductive pattern and the first connection electrode may be formed in a same process operation, and the second conductive pattern and the second connection electrode may be formed in a same process operation.

The insulation pattern may include a polymer.

In a plan view, the insulation pattern may be disposed inside the third contact hole.

In a plan view, the insulation pattern may be spaced apart from the first contact hole.

The fourth conductive pattern may include a first layer, a second layer disposed on the first layer, and a third layer disposed on the second layer, and the first layer and the third layer include titanium (Ti) and the second layer may include aluminum (Al).

The non-display area may include a first area adjacent to the display area, a second area spaced apart from the first area, and a bending area disposed between the first area and the second area, and the second area may include the pad area.

According to an embodiment, a display module may include a display panel including a display area including a pixel, and a non-display area including a pad area, in which a signal pad connected to the pixel through a signal line is disposed, and being adjacent to the display area, and an input sensing part including a first sensing conductive layer disposed on the display panel, a first sensing insulation layer disposed on the first sensing conductive layer, and a second sensing conductive layer disposed on the first sensing insulation layer. The signal pad may include a first conductive pattern connected to a distal end of the signal line, a second conductive pattern disposed on the first conductive pattern, a third conductive pattern disposed on the second conductive pattern, a fourth conductive pattern disposed on the third conductive pattern, and at least one insulation pattern disposed between the third conductive pattern and the fourth conductive pattern. The third conductive pattern and the first sensing conductive layer include a same material, and the fourth conductive pattern and the second sensing conductive layer include a same material.

A thickness of the third conductive pattern and a thickness of the first sensing conductive layer may be same, and a thickness of the fourth conductive pattern and a thickness of the second sensing conductive layer may be same.

The third conductive pattern and the first sensing conductive layer may be formed in a same process operation, and the fourth conductive pattern and the second sensing conductive layer may be formed in a same process operation.

The fourth conductive pattern may include a first layer, a second layer disposed on the first layer, and a third layer disposed on the second layer, and the first layer and the third layer include titanium (Ti) and the second layer may include aluminum (Al).

The signal pad may further include a first pad insulation layer disposed on a distal end of the signal line, and including a first contact hole exposing a portion of the distal end of the signal line, a second pad insulation layer disposed on the second conductive pattern, and including a second contact hole exposing a portion of the second conductive pattern, and a third pad insulation layer disposed on the third conductive pattern, and including a third contact hole exposing a portion of the third conductive pattern. The first conductive pattern may be disposed on the first pad insulation layer, and may be connected to a distal end of the signal line through the first contact hole, the third conductive pattern may be disposed on the second pad insulation layer, and may be connected to the second conductive pattern through the second contact hole, and the fourth conductive pattern may be disposed on the third pad insulation layer, and is connected to the third conductive pattern through the third contact hole.

The display area may include a base layer, a circuit element layer disposed on the base layer, and a light emitting element layer including a light emitting element and disposed on the circuit element layer. The circuit element layer may include a transistor, a first connection electrode connected to the transistor, and a second connection electrode connected to the first connection electrode and the light emitting element. The first conductive pattern and the first connection electrode may be disposed at a same layer, and the second conductive pattern and the second connection electrode may be disposed at a same layer.

The first conductive pattern and the first connection electrode may be formed in a same process operation, and the second conductive pattern and the second connection electrode may be formed in a same process operation.

The insulation pattern may include a polymer.

At least one of the first sensing conductive layer and the second sensing conductive layer may include a mesh opening.

According to an embodiment, an electronic device may include a display module including a display panel including a display area including a pixel and a non-display area including a pad area and being adjacent to the display area, and an input sensing part disposed on the display panel, an electronic component including a bump electrode, and disposed in the pad area, and an adhesion layer that adheres the display panel and the electronic component. A signal pad connected to the pixel through a signal line is disposed in the pad area, and the input sensing part may include a first sensing conductive layer disposed on the display panel, a first sensing insulation layer disposed on the first sensing conductive layer, and a second sensing conductive layer disposed on the first sensing insulation layer. The signal pad may include a first conductive pattern connected to a distal end of the signal line, a second conductive pattern disposed on the first conductive pattern, a third conductive pattern disposed on the second conductive pattern, a fourth conductive pattern disposed on the third conductive pattern, and at least one insulation pattern overlapping the bump electrode in a plan view, and disposed between the third conductive pattern and the fourth conductive pattern. The third conductive pattern and the first sensing conductive layer may include a same material, and the fourth conductive pattern and the second sensing conductive layer may include a same material.

### BRIEF DESCRIPTION OF THE DRAWINGS

The above and other objects and features of the disclosure will become apparent by describing in detail embodiments thereof with reference to the accompanying drawings.

FIG. 1 is a perspective view of a coupled state of an electronic device according to an embodiment of the disclosure.

FIG. 2 is an exploded perspective view of an electronic device according to an embodiment of the disclosure.

FIG. 3 is a schematic cross-sectional view of a display module according to an embodiment of the disclosure.

FIG. 4 is a plan view of a display panel according to an embodiment of the disclosure.

FIG. 5 is a plan view of an input sensing unit according to an embodiment of the disclosure.

FIG. 6 is a schematic cross-sectional view of a display module according to an embodiment of the disclosure.

FIG. 7 is a perspective view of an electronic device according to an embodiment of the disclosure.

FIG. 8A is a plan view of a pad area according to an embodiment of the disclosure.

FIGS. 8B and 8C are schematic cross-sectional views of a pad area according to an embodiment of the disclosure, respectively.

FIG. 8D is a schematic cross-sectional view of an electronic device according to an embodiment of the disclosure.

FIGS. 9A, 9B, 10A, 10B, and 10C are plan views of a pad area according to an embodiment of the disclosure, respectively.

### DETAILED DESCRIPTION OF THE EMBODIMENTS

The disclosure may be modified in various ways and may take various forms, and embodiments are illustrated in the drawings and described in detail in the specification. However, this is not intended to limit the disclosure to specific disclosed forms, but should be understood to include all modifications, equivalents, or substitutes included in the spirit and technical scope of the disclosure.

A singular expression includes a plural expression unless an exemption is explicitly described in the context.

When the terms, such as “comprise” and/or “comprising”, is used in the specification, it should be understood that they specify presence of the above-mentioned features, numbers, steps, operations, components, parts, and/or combinations thereof, and do not exclude presence or addition of one or more other numbers, steps, operations, components, parts, and/or combinations thereof.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the X-axis, the Y-axis, and the Z-axis are not limited to three axes of a rectangular coordinate system, such as the x, y, and z axes, and may be interpreted in a broader sense. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification, the expression of “directly disposed” may mean that none of a layer, a film, an area, and a plate is added between a part, such as the layer, the film, the area, and the plate, and another part. For example, the expression of “directly disposed” may mean that the two layers or two members are disposed while an additional member, such as an adhesive member, is not used therebetween.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Unless defined differently, all the terms including technical or scientific terms have the same meanings as those generally understood by an ordinary person in the art, to which the disclosure pertains. The terms, such as the terms defined in dictionaries, which are generally used, should be construed to coincide with the context meanings of the related technologies, and are not construed as ideal or excessively formal meanings unless explicitly defined in the disclosure.

The same reference numerals denote the same components. Furthermore, in the drawings, thicknesses, ratios, dimensions of the components are exaggerated for an effective description of the technical contents.

Hereinafter, a display panel, a display module, and an electronic device according to an embodiment of the disclosure will be described with reference to the drawings.

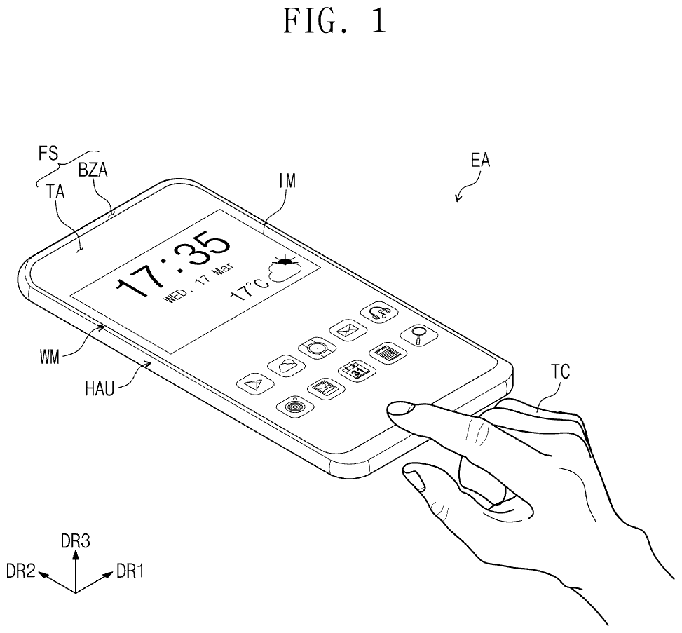

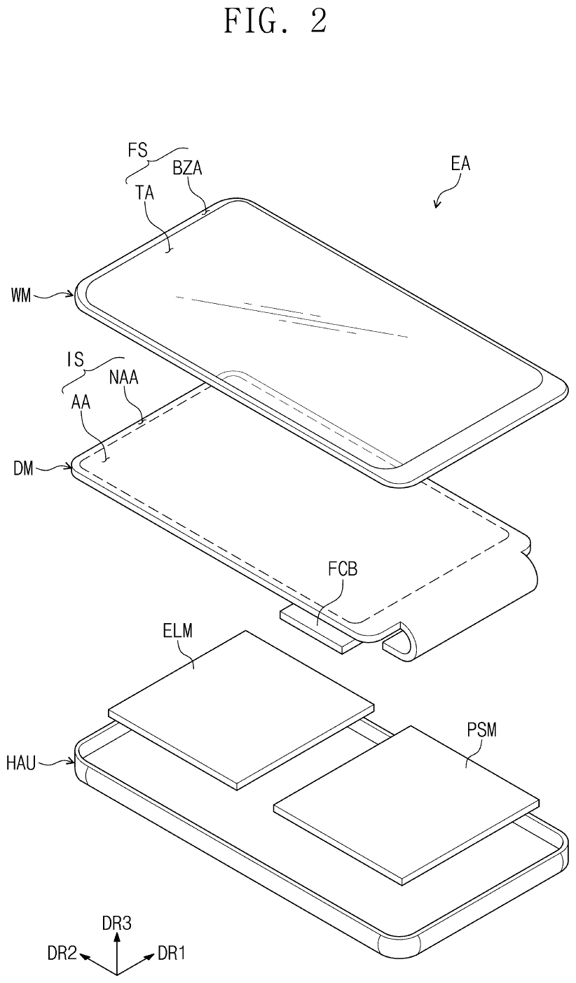

FIG. 1 is a perspective view of a coupled state of an electronic device EA according to an embodiment of the disclosure. FIG. 2 is an exploded perspective view of an electronic device EA according to an embodiment of the disclosure.

Referring to FIGS. 1 and 2, the electronic device EA may be a device that is activated in response to an electrical signal, displays an image IM, and senses an external input TC. For example, the electronic device EA may be a device, such as a monitor, a mobile phone, a tablet, a navigation device, and a game console. However, the electronic device EA is not limited thereto. In FIG. 1, a mobile phone is illustrated as an embodiment of the electronic device EA.

The electronic device EA may have a rectangular shape in a plan view, having short sides that extend in a first direction DR1, and long sides that extend in a second direction DR2 intersecting the first direction DR1. However, the disclosure is not limited thereto, and the electronic device EA may have various shapes, such as a circle or a polygon, in a plan view.

In an embodiment, a third direction DR3 may be defined as a direction that is perpendicular to a plane that is defined by the first direction DR1 and the second direction DR2. A front surface (or an upper surface) and a rear surface (or a lower surface) of each of the members that constitute the electronic device EA may face each other in the third direction DR3, and a normal direction of each of the front surface and the rear surface may be substantially parallel to the third direction DR3. A spacing distance between the front surface and the rear surface, which is defined along the third direction DR3, may correspond to a thickness of the member.

In the specification, “on a plane” or “in a plan view” may be defined as a state, in which it is viewed from the third direction DR3. In the specification, “on a cross-section” or “in a cross-sectional view” may be defined as a state, in which it is viewed from the first direction DR1 or the second direction DR2. Directions that are indicated by the first to third directions DR1, DR2, and DR3 may be converted into other directions as relative concepts.

The electronic device EA may be rigid or flexible. The term “flexible” may mean a flexible characteristic, and may include from a completely foldable structure to a structure that may be bent at a level of several nanometers. For example, the electronic device EA may be a curved electronic device, a rollable electronic device, or a foldable electronic device.

The electronic device EA may display the image IM through a display surface FS that is parallel to the first direction DR1 and the second direction DR2. The image IM may include a still image as well as a dynamic image. As an example of the image IM in FIG. 1, a clock and icons are illustrated.

The display surface FS of the electronic device EA may include only a flat surface, or may include a curved surface that is bent from at least one side of the flat surface. The display surface FS may correspond to a front surface of the electronic device EA, and at the same time, may correspond to a front surface of a window WM. Hereinafter, the same reference numerals are used for the display surface FS of the electronic device EA and the front surface FS of the window WM.

The electronic device EA according to an embodiment may sense an external input TC that is applied from the outside. The external input TC may include various types of inputs, such as a force, pressure, a temperature, or light. In FIG. 1, the external input TC is illustrated as a hand of the user, which is applied to the front surface of the electronic device EA according to an embodiment. However, the disclosure is not limited thereto, and the external input TC may include an input, such as a contact by a pen or hovering, that is applied close to the electronic device EA.

The electronic device EA may sense an input by the user, through the display surface FS defined on the front surface, and may respond to the sensed input signal. However, an area of the electronic device EA, which senses the external input TC, is not limited to the front surface of the electronic device EA, but may be changed depending on a design of the electronic device EA. For example, the electronic device EA may sense the input by the user, which is applied to a side surface or a rear surface of the electronic device EA.

The electronic device EA may include a window WM, a display module DM, an electronic module ELM, a power source module PSM, and a housing HAU. The window WM and the housing HAU may be coupled to each other to constitute an external appearance of the electronic device EA.

The window WM may be disposed on the display module DM. The window WM may cover the front surface IS of the display module DM, and may protect the display module DM from external impacts and scratches. The window WM may be coupled to the display module DM by an adhesion layer.

The window WM may include an optically transparent insulating material. For example, the window WM may include glass or a synthetic resin as a base film. The window WM may have a single-layered or multi-layered structure. For example, the window WM having the multi-layered structure may include synthetic resin films that are coupled to each other by an adhesive, or may include a glass film and a synthetic resin film that are coupled to each other by an adhesive. The window WM may further include a functional layer, such as an anti-fingerprint layer, a phase control layer, and a hard coating layer, which is disposed on the transparent base film.

The front surface FS of the window WM may correspond to the front surface FS of the electronic device EA. The front surface FS of the window WM may include a transmission area TA and a bezel area BZA.

The transmission area TA may be an optically transparent area. The transmission area TA may transmit the image IM provided by the display module DM. In FIG. 1, the transmission area TA is illustrated in a rectangular shape, but the disclosure is not limited thereto, and the transmission area TA may have various shapes.

The bezel area BZA may be an area having a lower light transmittance than the transmission area TA. The bezel area BZA may correspond to an area, on which a material having a color is printed. The bezel area BZA may prevent transmission of light to prevent a configuration of the display module DM disposed to overlap the bezel area BZA in a plan view from being visually recognized from the outside.

The bezel area BZA may be adjacent to the transmission area TA. The shape of the transmission area TA may be substantially defined by the bezel area BZA. For example, the bezel area BZA may be disposed outside the transmission area TA to surround the transmission area TA. However, the disclosure is not limited thereto, and the bezel area BZA may be disposed adjacent to only one side of the transmission area TA or on a side surface other than the front surface of the electronic device EA. In another embodiment, the bezel area BZA may be omitted.

The display module DM may be disposed between the window WM and the housing HAU. The display module DM may display an image IM, and may sense an external input TC. The image IM may be displayed on the front surface IS of the display module DM. The front surface IS of the display module DM may include an active area AA and a peripheral area NAA.

The active area AA may be an area activated in response to an electrical signal. For example, the active area AA may be an area, in which an image IM is displayed, and an area, in which an external input TC is sensed, at the same time. The active area AA may overlap at least a portion of the transmission area TA in a plan view. Accordingly, the user may view the image IM through the transmission area TA or provide an external input TC. However, the disclosure is not limited thereto, and in another embodiment, an area, in which the image IM is displayed, and an area, in which the external input TC is sensed, may be separated from each other, in the active area AA.

The peripheral area NAA may be adjacent to the active area AA. For example, the peripheral area NAA may surround the active area AA. In the peripheral area NAA, a driving circuit or a driving wiring line for driving the active area AA may be disposed. The peripheral area NAA may overlap at least a portion of the bezel area BZA in a plan view, and the components disposed in the peripheral area NAA may be prevented from being visually recognized from the outside due to the bezel area BZA.

The display module DM may include a display panel and an input sensing unit (or input sensing part). The display panel may display an image IM, and the input sensing unit may sense an external input TC. A detailed description thereof will be made below.

A portion of the display module DM may be bendable around a bending axis that extends in the first direction DR1. For example, a portion of the display module DM may be bendable toward a rear surface of the display module DM, which corresponds to the active area AA. A flexible circuit board FCB may be connected to a portion of the display module DM, and thus, the flexible circuit board FCB may overlap the display module DM in a plan view.

The flexible circuit board FCB may be electrically connected to the display module DM on a side of the display module DM. The flexible circuit board FCB may generate an electrical signal provided to the display module DM or receive a signal generated by the display module DM to calculate a result value including position, at which the external input TC is sensed, or intensity information.

An electronic module ELM and a power source module PSM may be disposed under the display module DM. The electronic module ELM and the power source module PSM may be electrically connected to each other through a separate circuit board.

The power source module PSM may supply electric power for an operation of the electronic device EA. For example, the power source module PSM may include a battery module.

The electronic module ELM may include various functional modules for operating the electronic device EA. For example, the electronic module ELM may include a control module, a wireless communication module, an image input module, an audio input module, an audio output module, a memory, an optical module, and an external interface module. The electronic module ELM may include a main circuit board, and the modules of the electronic module ELM may be mounted on the main circuit board or may be electrically connected to the main circuit board through a separate circuit board.

The control module of the electronic module ELM may control an overall operation of the electronic device EA. For example, the control module may activate or deactivate the display module DM according to a user input. The control module may include at least one microprocessor. The optical module of the electronic modules ELM may include a camera module, a proximity sensor, a biometric sensor that recognizes a part (e.g., a fingerprint, an iris, or a face) of the body of the user, or a lamp that outputs light.

The housing HAU may be coupled to the window WM to provide an internal space for receiving the display module DM, the electronic module ELM, the power source module PSM, and the flexible circuit board FCB. The housing HAU may include a material having a relatively high rigidity. For example, the housing HAU may include multiple frames and/or plates including glass, a plastic, a metal, or a combination thereof. The housing HAU may protect the components of the electronic device EA stored in the housing HAU by absorbing an impact applied from the outside or preventing foreign matters/moisture that introduced from the outside.

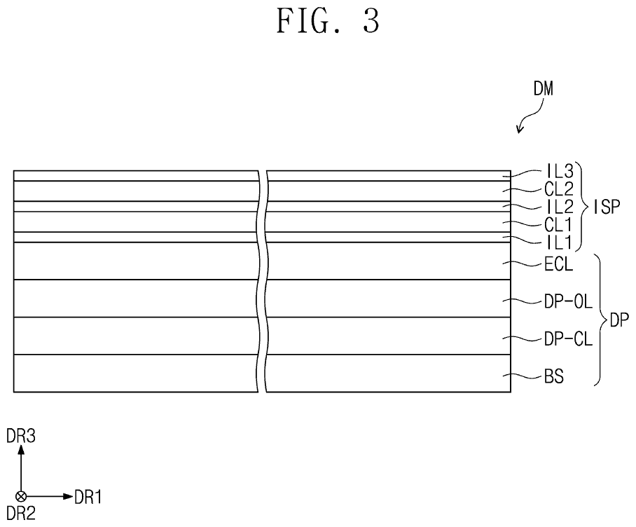

FIG. 3 is a schematic cross-sectional view of a display module DM according to an embodiment of the disclosure.

Referring to FIG. 3, the display module DM may include a display panel DP and an input sensing unit (or input sensing part) ISP. The input sensing unit ISP may be disposed on the display panel DP. For example, the input sensing unit ISP may be disposed on (e.g., directly on) the display panel DP. In an embodiment, “the input sensing unit ISP is disposed directly on the display panel DP” may mean that the input sensing unit ISP is formed on the display panel DP through a continuous process, and the input sensing unit ISP and the display panel DP are coupled to each other without a separate addition layer. For example, the components of the input sensing unit ISP may be formed on the base surface provided in the display panel DP.

The display panel DP may display an image in response to an electrical signal. The display panel DP according to an embodiment may be a light emitting display panel, but the disclosure is not particularly limited thereto. For example, the display panel DP may be an organic light emitting display panel, an inorganic light emitting display panel, or a quantum dot light emitting display panel. A light emission layer of the organic light emitting display panel may include an organic light emitting material, and a light emission layer of the inorganic light emitting display panel may include an inorganic light emitting material. A light emission layer of the quantum dot light emitting display panel may include a quantum dot and a quantum rod. Hereinafter, the display panel DP is described as an organic light emitting display panel.

The display panel DP may include a base substrate BS, a circuit element layer DP-CL, a light emitting element layer DP-OL, and an encapsulation layer ECL that are sequentially laminated along the third direction DR3.

The base substrate BS may be a rigid substrate or a flexible substrate that may be bent, folded, or rolled. For example, the base substrate BS may be a glass substrate, a metal substrate, or a polymer substrate. The base substrate BS may provide a base surface, on which the circuit element layer DP-CL is disposed.

The base substrate BS may include an inorganic layer, an organic layer, or a composite material layer. The base substrate BS may have a single-layered or multi-layered structure. For example, the base substrate BS having a multi-layered structure may include synthetic resin layers, and a multilayer or single-layer inorganic layer disposed between the synthetic resin layers. The synthetic resin layer may include an acrylic resin, a methacrylic resin, a polyisoprene, a vinyl resin, an epoxy resin, a urethane resin, a cellulose resin, a siloxane resin, a polyamide resin, a perylene resin, or the like, but the material of the synthetic resin layer is not limited thereto.

The circuit element layer DP-CL may be disposed on the base substrate BS. The circuit element layer DP-CL may include at least one insulation layer, a semiconductor pattern, and a conductive pattern. The insulation layer, the semiconductor pattern, and the conductive pattern included in the circuit element layer DP-CL may form driving elements, such as transistors, signal lines, and pads.

The light emitting element layer DP-OL may be disposed on the circuit element layer DP-CL. The light emitting element layers DP-OL may include light emitting elements, each of which emits light. For example, the light emitting elements may include an organic light emitting element, an inorganic light emitting element, a micro LED, or a nano LED. The light emitting elements of the light emitting element layer DP-OL may be electrically connected to the driving elements of the circuit element layer DP-CL to emit light in response to electrical signals provided by the driving elements.

The encapsulation layer ECL may be disposed on the light emitting element layer DP-OL to seal the light emitting elements. The encapsulation layer ECL may include at least one thin film for improving an optical efficiency of the light emitting element layer DP-OL or protecting the light emitting element layer DP-OL. For example, the encapsulation layer ECL may include at least one of an inorganic film and an organic film. The inorganic film of the encapsulation layer ECL may protect the light emitting elements from moisture/oxygen. The organic film of the encapsulation layer ECL may protect the light emitting elements from foreign substances, such as dust particles.

The input sensing unit ISP may sense an external input, and may provide an input signal including information on the external input so that the display panel DP may display an image corresponding to the external input. The input sensing unit ISP may be driven in various ways, such as a capacitive method, a resistive method, an infrared method, a sound wave method, or a pressure method, and the driving method of the input sensing unit ISP is not limited to any one as long as an external input may be sensed. In an embodiment, the input sensing unit ISP is described as an input sensing panel that is driven by a capacitive method according to an embodiment.

The input sensing unit ISP may include a base layer IL1, a first sensing conductive layer CL1, a first sensing insulation layer IL2, a second sensing conductive layer CL2, and a second sensing insulation layer IL3. The base layer IL1 of the input sensing unit ISP may contact the encapsulation layer ECL. However, the disclosure is not limited thereto, and at least one of the base layer IL1 or the second sensing insulation layer IL3 may be omitted.

Each of the first sensing conductive layer CL1 and the second sensing conductive layer CL2 may have a single-layered or multi-layered structure. The conductive layer of the multi-layer structure may include at least two or more of transparent conductive layers and metal layers. The conductive layer of the multi-layer structure may include metal layers including different metals. The transparent conductive layer may include at least one of indium tin oxide (ITO), indium zinc oxide (IZO), zinc oxide (ZnO), indium tin oxide (ITZO), PEDOT, metal nanowire, and graphene. The metal layer may include at least one of molybdenum, silver, titanium, copper, aluminum, and an alloy thereof. For example, each of the first sensing conductive layer CL1 and the second sensing conductive layer CL2 may have a two-layer structure, for example, a two-layer structure of ITO/copper, or may have a three-layer structure of titanium/aluminum/titanium, but the disclosure is not limited thereto.

Each of the first sensing conductive layer CL1 and the second sensing conductive layer CL2 may have sensing conductive patterns. The sensing conductive patterns of the first sensing conductive layer CL1 and the second sensing conductive layer CL2 may form sensing electrodes that constitute the input sensing unit ISP, and sensing lines that are connected the sensing electrodes.

Each of the base layer IL1, the first sensing insulation layer IL2, and the second sensing insulation layer IL3 may include at least one of an inorganic film and an organic film. For example, the inorganic film may include at least one of aluminum oxide, titanium oxide, silicon oxide, silicon oxynitride, zirconium oxide, and hafnium oxide, and the organic film may include at least one of an acrylic resin, a methacrylic resin, a polyisoprene resin, a vinyl resin, an epoxy resin, a urethane resin, a cellulose resin, a siloxane resin, a polyimide resin, a polyamide resin, and a perylene resin. However, materials of the inorganic film and the organic film are not limited to the above examples. In an embodiment, the base layer IL1 may include an organic film, and the first sensing insulation layer IL2 and the second sensing insulation layer IL3 may include an organic film, but the disclosure is not limited thereto.

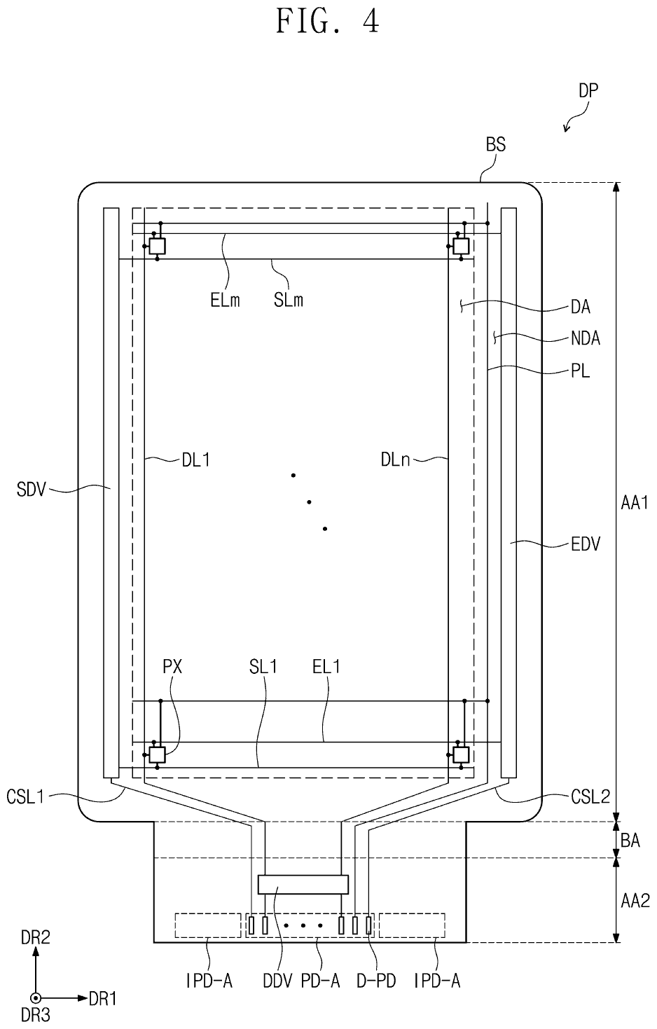

FIG. 4 is a plan view of a display panel DP according to an embodiment of the disclosure.

Referring to FIG. 4, the display panel DP may include a base substrate BS, pixels PX, signal lines SL1 to SLm, DL1 to DLn, EL1 to ELm, CSL1, CSL2, and PL, a scan driver SDV, an emission driver EDV, a data driver DDV, and display pads D-PD.

The base substrate BS may provide a base surface, on which electrical elements, lines, and the like of the display panel DP are disposed. The base substrate BS may include a first base area AA1, a bending area BA, and a second base area AA2 that are distinguished from each other in the second direction DR2. The bending area BA may extend from the first base area AA1 in the second direction DR2. The second base area AA2 may extend from the bending area BA in the second direction DR2. Accordingly, the first base area AA1 and the second base area AA2 may be spaced apart from each other with the bending area BA interposed between the first base area AA1 and the second base area AA2.

The first base area AA1 may include a display area DA. The display area DA may be an area, in which light emitting elements of the pixels PX are disposed. Accordingly, the pixels PX may display an image through the display area DA. The display area DA may correspond to an active area AA (see FIG. 2) of the display module DM (see FIG. 2), and may overlap a transmission area TA (see FIG. 2) of the window WM (see FIG. 2) in a plan view.

The remaining of the first base area AA1, bending area BA, and second base area AA2, other than the display area DA, may be defined as a non-display area NDA. The non-display area NDA may be an area that is adjacent to the display area DA and does not display an image. In an embodiment, the non-display area NDA may surround the display area DA. In the non-display area NDA, display pads D-PD that are electrically connected to the scan driver SDV, the emission driver EDV, and the data driver DDV for driving the pixels PX, and the signal lines SL1 to SLm, DL1 to DLn, EL1 to ELm, CSL1, CSL2, and PL may be disposed. The signal lines SL1 to SLm, DL1 to DLn, EL1 to DLn, CSL1, CSL2, and PL electrically connected to the pixels PX may be disposed in the non-display area NDA to extend.

The bending area BA may be an area, that is bendable around a bending axis that extends in the first direction DR1. For example, the bending area BA may be bendable toward a rear surface of the display panel DP, which corresponds to the first base area AA1. The second base area AA2 that extends from a side of the bending area BA may overlap the first base area AA1 in a plan view as the bending area BA is bent. For example, the second base area AA2 may be disposed on a rear surface of the display panel DP, which corresponds to the first base area AA1.

A width of each of the bending area BA and the second base area AA2 in the first direction DR1 may be smaller than a width of the first base area AA1. Because the bending area BA has a smaller width than the first base area AA1 in a direction that is parallel to the bending axis, the bending area BA may be readily bent. However, the disclosure is not limited thereto, and at least one of the widths of the bending area BA and the second base area AA2 in the first direction DR1 and the width of the first base area AA1 may be the same.

The second base area AA2 may be an area that is located under the first base area AA1 to be flat as the bending area BA is bent. The second base area AA2 may be an area, in which, among the signal lines SL1 to SLm, DL1 to DLn, EL1 to ELm, CSL1, CSL2, and PL, the signal lines that extend toward the display pads D-PD toward the display pad D-PD via the bending area BA and the driver chip DDV are disposed.

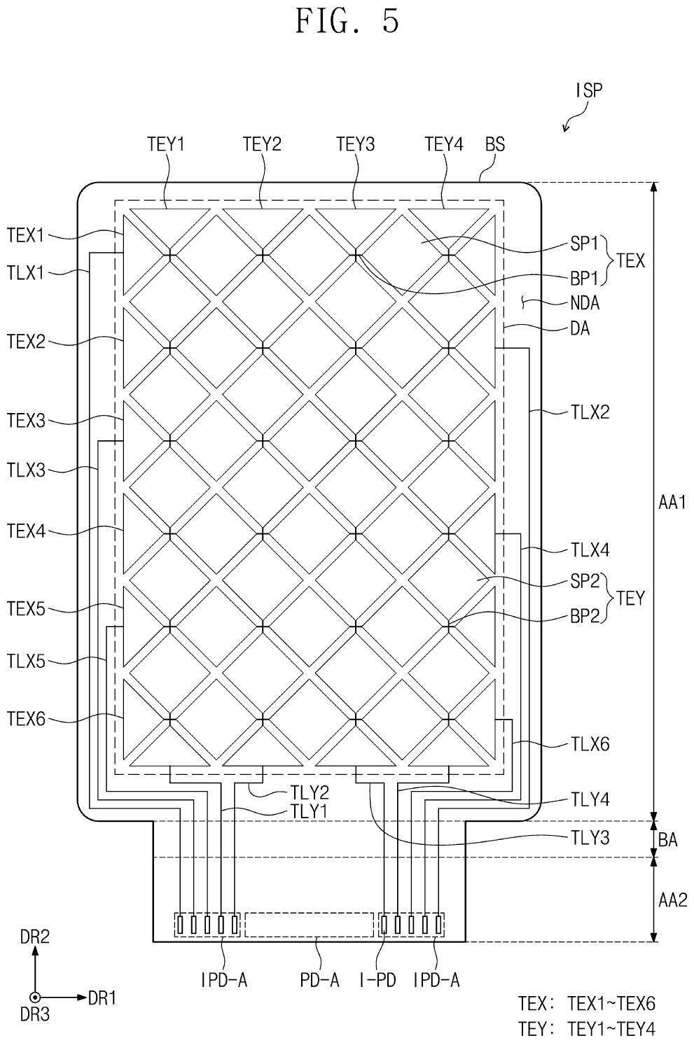

An area, in which the display pads D-PD are disposed, and an area in which the sensing pads I-PD (see FIG. 5) that will be described below are disposed, may be classified into a display pad area PD-A and a sensing pad area IPD-A, respectively. FIG. 4 schematically illustrates that the display pad area PD-A and the sensing pad area IPD-A are distinguished from each other in the first direction DR1. For example, the sensing pad area IPD-A may be provided adjacent to opposite sides of the second base area AA2 in the first direction DR1, and the display pad area PD-A may be provided at a central portion. However, the disclosure is not limited thereto, and the arrangement positions of the display pads D-PD and the sensing pads I-PD (see FIG. 5) may be variously changed.

The flexible circuit board FCB (refer to FIG. 2) may be disposed on the second base area AA2, in which the display pads D-PD and the sensing pads I-PD (see FIG. 5) are disposed, and may be electrically connected to the display pads D-PD and the sensing pads I-PD (see FIG. 5). The flexible circuit board FCB (see FIG. 2) that is disposed adjacent to a lower end of the second base area AA2 may be located on a rear surface of the display panel DP as the bending area BA is bent. As the second base area AA2 and the flexible circuit board FCB (see FIG. 2) are located under the first base area AA1 on the front surface of the electronic device EA (refer to FIG. 2), an area of a bezel of the electronic device EA (see FIG. 2) may decrease.

Each of the pixels PX may include a pixel driving circuit including transistors (e.g., a switching transistor, a driving transistor, and the like) and at least one capacitor, and a light emitting element that is electrically connected to the pixel driving circuit. The pixels PX may generate light in response to an electrical signal that is applied to the pixels PX, and may display an image through the display area DA. According to an embodiment, some of the pixels PX may include transistors that are disposed in the non-display area NDA, but the disclosure is not limited thereto.

The scan driver SDV and the emission driver EDV may be disposed in the non-display area NDA in the first base area AA1. The data driver DDV may be disposed in the non-display area NDA in the second base area AA2. In an embodiment, the data driver DDV may be provided in the form of an integrated circuit chip that is mounted in the non-display area NDA of the display panel DP. However, the disclosure is not limited thereto, and in another embodiment, the data driver DDV may be mounted on a flexible circuit board FCB (see FIG. 2).

The signal lines SL1 to SLm, DL1 to DLn, EL1 to ELm, CSL1, CSL2, and PL may include scan lines SL1 to SLm, data lines DL1 to DLn, light emission lines EL1 to ELm, first and second control lines CSL1 and CSL2, and a power line PL. “m” and “n” may be natural numbers.

The data lines DL1 to DLn may be insulated from the scan lines SL1 to SLm and the light emission lines EL1 to ELm while intersecting the scan lines SL1 to SLm and the light emission lines EL1 to Elm. For example, the scan lines SL1 to SLm may extend in the first direction DR1, and may be electrically connected to the scan driver SDV. The data lines DL1 to DLn may extend in the second direction DR2, and may be electrically connected to the data driver DDV. The light emission lines EL1 to ELm may extend in the first direction DR1, and may be electrically connected to the emission driver EDV.

The power line PL may include a portion that extends in the first direction DR1 and a portion that extends in the second direction DR2. The portion of the power line PL, which extends in the first direction DR1, and the portion of the power line PL, which extends in a second direction DR2, may be disposed on different layers or may be integrally disposed at a same layer. A portion of the power line PL, which extends in the first direction DR1, may be electrically connected to the pixels PX, and a portion that extends in the second direction DR2. A portion of the power line PL, which extends in the second direction DR2, may be disposed in the non-display area NDA, and may be electrically connected to the display pads D-PD via the bending area BA and the second base area AA2 from the first base area AA1. The power line PL may provide a first voltage to the pixels PX.

The first control line CSL1 may be electrically connected to the scan driver SDV, and may extend toward a lower end of the second base area AA2 via the bending area BA. The second control line CSL2 may be electrically connected to the emission driver EDV, and may extend toward the lower end of the second base area AA2 via the bending area BA.

The display pads D-PD may be disposed adjacent to the lower end of the second base area AA2. In the second base area AA2, the display pads D-PD may be disposed closer to the lower end of the base substrate BS than the data driver DDV. The display pads D-PD may be spaced apart from each other in the first direction DR1. The power line PL, the first control line CSL1, and the second control line CSL2 may be electrically connected to corresponding ones of the display pads D-PD, respectively. Each of the data lines DL1 to DLn may be electrically connected to a corresponding one of the display pads D-PD through the data driver DDV.

The display pads D-PD may be electrically connected to the flexible circuit board FCB (see FIG. 2) through an adhesion layer, and an electrical signal provided from the flexible circuit board FCB (see FIG. 2) may be transmitted to the display panel DP through the display pads D-PD. However, a method of connecting the display pads D-PD to the flexible circuit board FCB (see FIG. 2) is not limited thereto.

The scan driver SDV may generate scan signals in response to a scan control signal. The scan signals may be applied to the pixels PX through the scan lines SL1 to SLm. The data driver DDV may generate data voltages corresponding to the image signals in response to the data control signal. The data voltages may be applied to the pixels PX through data lines DL1 to DLn. The emission driver EDV may generate light emission signals in response to a light emission control signal. The light emission signals may be applied to the pixels PX through the light emission lines EL1 to ELm.

The pixels PX may receive data voltages in response to the scan signals. The pixels PX may generate an image by emitting light having a luminance corresponding to data voltages in response to the light emission signals. A light emission time period of the pixels PX may be controlled by the light emission signals.

FIG. 5 is a plan view of the input sensing unit ISP according to an embodiment of the disclosure. FIG. 5 schematically illustrates the components of the input sensing unit ISP disposed on the base substrate BS for convenience of description.

In an embodiment, the input sensing unit ISP may be driven in a mutual-cap type. Referring to FIG. 5, the input sensing unit ISP may include first sensing electrodes TEX1 to TEX6, second sensing electrodes TEY1 to TEY4, first sensing lines TLX1 to TLX6, second sensing lines TLY1 to TLX4, and sensing pads I-PD. However, the disclosure is not limited thereto, and the input sensing unit ISP may be driven in a self-cap type.

Each of the first sensing electrodes TEX may extend in the first direction DR1, and the first sensing electrodes TEX may be arranged in the second direction DR2. FIG. 5 illustrates six first sensing electrodes TEX1 to TEX6 according to an embodiment. However, the number of the first sensing electrodes TEX included in the input sensing unit ISP is not limited thereto. A first sensing electrode TEX may include first sensing patterns SP1 that are arranged in the first direction DR1, and first connection patterns BP1 that connect the first sensing patterns SP1.

Each of the second sensing electrodes TEY may extend in the second direction DR2, and the second sensing electrodes TEY may be arranged in the first direction DR1. FIG. 5 illustrates four second sensing electrodes TEY1 to TEY4 according to an embodiment. However, the number of the second sensing electrodes TEY included in the input sensing unit ISP is not limited thereto. A second sensing electrode TEY may include second sensing patterns SP2 that are arranged along the second direction DR2, and second connection patterns BP2 that connects the second sensing patterns SP2.

The first sensing electrodes TEX and the second sensing electrodes TEY may be electrically insulated from each other. The input sensing unit ISP may sense an external input through a change in a capacitance between the first sensing electrodes TEX and the second sensing electrodes TEY. The first sensing electrodes TEX and the second sensing electrodes TEY may be disposed in an area corresponding to the display area DA of the base substrate BS. Accordingly, the electronic device EA (see FIG. 1) may display an image through the display area DA, and may sense an external input applied to the display area DA at the same time.

The first sensing lines TLX1 to TLX6 may be disposed in the non-display area NDA, and may be electrically connected to the first sensing electrodes TEX1 to TEX6, respectively. Some of the first sensing lines TLX1 to TLX6 may be disposed in the left side of the non-display area NDA, and the remaining ones may be disposed in the right side of the non-display area NDA. For example, the first sensing lines TLX1, TLX3, and TLX5 connected to the first sensing electrodes TEX1, TEX3, and TEX5 disposed in odd rows may be connected to left sides of the first sensing electrodes TEX1, TEX3, and TEX5, respectively, and the first sensing lines TLX2, TLX4, and TLX6 connected to the first sensing electrodes TEX2, TEX4, and TEX6 disposed in even rows may be connected to right sides of the first sensing electrodes TEX2, TEX4, and TEX6, respectively. However, the disposition of the first sensing lines TLX1 to TLX6 is not limited thereto, and all of the first sensing lines TLX1 to TLX6 may be disposed in the left side of the non-display area NDA, or all of the first sensing lines TLX1 to TLX6 may be disposed in the right side of the non-display area NDA.

Each of the first sensing lines TLX1 to TLX6 may extend from the first base area AA1 toward the second base area AA2 via the bending area BA. Each of the first sensing lines TLX1 to TLX6 may be electrically connected to the sensing pads I-PD that are disposed in the second base area AA2.

The second sensing lines TLY1 to TLY4 may be disposed in the non-display area NDA, and may be electrically connected to the second sensing electrodes TEY1 to TEY4, respectively. Some of the second sensing lines TLY1 to TLY4 may be disposed adjacent to the left side of the non-display area NDA, and the remaining ones may be disposed adjacent to the right side of the non-display area NDA. For example, in the first direction DR1, among the second sensing electrodes TEY1 to TEY4, the second sensing lines TLY1 and TLY2 that are electrically connected to the second sensing electrodes TEY1 and TEY2 disposed on the left side may be disposed adjacent to the left side of the first base area AA1, and the second sensing lines TLY3 and TLY4 that are electrically connected to the second sensing electrodes TEY3 and TEY4 disposed on the right side may be disposed adjacent to the right side of the first base area AA1. However, the disposition of the second sensing lines TLY1 to TLY4 is not limited thereto.

Each of the second sensing lines TLY1 to TLY4 may extend from an area that is adjacent to a lower end of the first base area AA1 toward the second base area AA2 via the bending area BA. The second sensing lines TLY1 to TLY4 may be electrically connected to the sensing pads I-PD disposed in the second base area AA2, respectively.

Some of the sensing pads I-PD may be disposed in an area that is adjacent to the left side of the second base area AA2 in the first direction DR1, and the remaining ones may be disposed in an area that is adjacent to the right side of the second base area AA2. For example, the sensing pads I-PD may be divided into two groups that are spaced apart from each other with the display pad area PD-A interposed between the two groups. However, the disposition of the sensing pads I-PD is not limited thereto.

The sensing pads I-PD and the display pads D-PD (see FIG. 4) may be disposed at a same layer. The sensing pads I-PD and the first and second sensing lines TLX1 to TLX6 and TLY1 to TLY4 may be disposed at different layers, and the sensing pads I-PD may be connected to each other through a contact hole. However, the disclosure is not limited thereto, and the sensing pads I-PD and the display pads D-PD (see FIG. 4) may be disposed at different layers. For example, the sensing pads I-PD and the first and second sensing lines TLX1 to TLX6 and TLY1 to TLY4 may be integrally formed at a same layer.

The first and second sensing lines TLX1 to TLX6 and TLY1 to TLY4 may be disposed on an upper side of the components of the display panel DP (see FIG. 4) in an area corresponding to the non-display area NDA of the base substrate BS. Accordingly, the first and second sensing lines TLX1 to TLX6 and TLY1 to TLY4 may overlap the components of the display panel DP (see FIG. 4) in a plan view in the bending area BA and the second base area AA2.

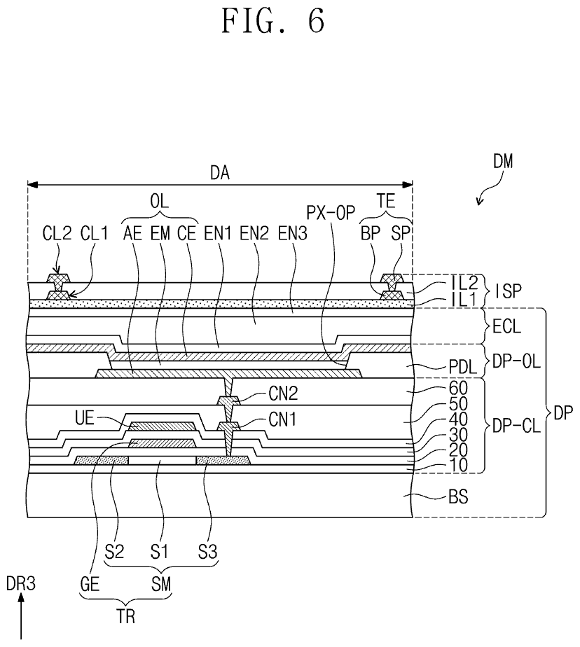

FIG. 6 is a schematic cross-sectional view of a display module DM according to an embodiment of the disclosure. FIG. 6 schematically illustrates a cross-sectional view of a pixel PX (see FIG. 4) that is disposed in the display area DA according to an embodiment.

Referring to FIG. 6, the display module DM may include a display panel DP, and an input sensing unit ISP that is disposed on the display panel DP. The above description may be applied to the components in the same way.

As described above in FIG. 3, the display panel DP may include a base substrate BS, a circuit element layer DP-CL, a light emitting element layer DP-OL, and an encapsulation layer ECL.

The base substrate BS may have insulating properties, and may provide a base surface, on which components of the display module DM are disposed. The base substrate BS may be flexible or bendable. As described above, the base substrate BS may include a first base area AA1 (see FIG. 4), a bending area BA (see FIG. 4), and a second base area AA2 (see FIG. 4), and the bending area BA (see FIG. 4) of the base substrate BS may be bendable with a curvature.

The circuit element layer DP-CL may include insulation layers 10 to 60 that are disposed on the base substrate BS, a transistor TR of a pixel PX (see FIG. 4), an upper electrode UE, and connection electrodes CN1 and CN2. The insulation layers 10 to 60 may include first to sixth insulation layers 10 to 60 that are sequentially laminated along a thickness direction on the base substrate BS. However, the insulation layers 10 to 60 included in the circuit element layer DP-CL are not limited thereto, and may be changed depending on the configuration or manufacturing process of the circuit element layer DP-CL.

The first insulation layer 10 may be disposed on the base substrate BS. The first insulation layer 10 may be provided as a barrier layer and/or a buffer layer that prevents foreign substances from being introduced from the outside. The first insulation layer 10 may improve a coupling force between the base substrate BS and the semiconductor pattern SM and/or the conductive pattern of the circuit element layer DP-CL. The first insulation layer 10 may include at least one of a silicon oxide layer and a silicon nitride layer. In an embodiment, the first insulation layer 10 may include silicon oxide layers and silicon nitride layers that are alternately laminated.

The pixel PX (see FIG. 4) may be disposed on the base substrate BS. The pixel PX (see FIG. 4) may be disposed in the display area DA. The pixel PX (see FIG. 4) may include a transistor TR and a light emitting element OL.

The transistor TR may include a semiconductor pattern SM and a gate electrode GE. The semiconductor pattern SM may be disposed on the first insulation layer 10. The semiconductor pattern SM may include a channel S1, a source S2, and a drain S3. The semiconductor pattern SM may include a silicon semiconductor, and may include a single crystalline silicon semiconductor, a polysilicon semiconductor, or an amorphous silicon semiconductor. However, the disclosure is not limited thereto, and in another embodiment, the semiconductor pattern SM may include an oxide semiconductor. The semiconductor pattern SM may be formed of various materials as long as it has semiconductor properties, and the disclosure is not limited to any one embodiment.

The semiconductor pattern SM may include multiple areas having different electrical characteristics depending on whether it is doped or reduced. For example, the semiconductor pattern SM may include an area having a high conductivity as it is doped or reduced in metal oxide, and the area having the high conductivity may serve as an electrode or a signal wiring line of the transistor TR. This may correspond to the source S2 and the drain S3 of the transistor TR. The semiconductor pattern SM may include an area that is not doped and thus has a relatively low conductivity, and may correspond to the channel S1 (or an active) of the transistor TR.

The second insulation layer 20 may be disposed on the first insulation layer 10 and cover the semiconductor pattern SM. The gate electrode GE may be disposed on the second insulation layer 20. The second insulation layer 20 may be disposed between the semiconductor pattern SM of the transistor TR and the gate electrode GE. The gate electrode GE may overlap the channel S1 of the semiconductor pattern SM in a plan view. The gate electrode GE may function as a mask in a process of doping the semiconductor pattern SM. The gate electrode GE may include molybdenum (Mo) having a heat resistance, an alloy including molybdenum, titanium (Ti), an alloy including titanium, and the like, but the disclosure is not limited thereto.

A structure of the transistor TR is not limited to the embodiment illustrated in FIG. 6. In another embodiment, the source S2 or the drain S3 of the transistor TR may be electrodes independently formed from the semiconductor pattern SM, and the source S2 and the drain S3 may contact the semiconductor pattern SM or may be electrically connected to the semiconductor pattern SM while passing through an insulation layer. In another embodiment, the gate electrode GE may be disposed under the semiconductor pattern SM. The transistor TR may be formed in various structures, and the disclosure is not limited to any one embodiment.

The second insulation layer 20 and the third to sixth insulation layers 30 to 60 that will be described below may include at least one of an inorganic layer and an organic layer. For example, the inorganic layer may include at least one of aluminum oxide, titanium oxide, silicon oxide, silicon oxynitride, zirconium oxide, and hafnium oxide. The organic layer may include at least one of an acrylic resin, a methacrylic resin, a polyisoprene, a vinyl resin, an epoxy resin, a urethane resin, a cellulose resin, a siloxane resin, a polyamide resin, and a perylene resin.

The third insulation layer 30 may be disposed on the second insulation layer 20, and may cover the gate electrode GE. The upper electrode UE may be disposed on the third insulation layer 30. The upper electrode UE may overlap the gate electrode GE in a plan view, and the gate electrodes GE and the upper electrode UE that overlap each other may form a capacitor.

The fourth insulation layer 40 may be disposed on the third insulation layer 30, and may cover the upper electrode UE. The connection electrodes CN1 and CN2 may include a first connection electrode CN1 and a second connection electrode CN2. The first connection electrode CN1 may be disposed on the fourth insulation layer 40. The fifth insulation layer 50 may be disposed on the fourth insulation layer 40 and cover the first connection electrode CN1. The second connection electrode CN2 may be disposed on the fifth insulation layer 50. The sixth insulation layer 60 may be disposed on the fifth insulation layer 50 and cover the second connection electrode CN2. In an embodiment, at least one of the fifth insulation layer 50 and the sixth insulation layer 60 may include an organic layer, and may provide a flat upper surface while covering steps between components that are disposed thereunder.

The first connection electrode CN1 may be electrically connected to the semiconductor pattern SM through a contact hole that passes through the second to fourth insulation layers 20 to 40. The second connection electrode CN2 may be electrically connected to the first connection electrode CN1 through a contact hole penetrating the fifth insulation layer 50.

Each of the first connection electrode CN1 and the second connection electrode CN2 may include a conductive material. Each of the first connection electrode CN1 and the second connection electrode CN2 may include at least one of gold, silver, copper, aluminum, platinum, molybdenum, titanium, and an alloy thereof. At least one of the first connection electrode CN1 and the second connection electrode CN2 may include conductive layers of a multi-layered structure. For example, at least one of the first connection electrode CN1 and the second connection electrode CN2 may have a three-layered structure of titanium/aluminum/titanium. However, the disclosure is not limited thereto.

According to an embodiment of the circuit element layer DP-CL, at least one of the first connection electrode CN1 and the second connection electrode CN2 may be omitted. According to another embodiment of the circuit element layer DP-CL, an additional connection electrode that connects the transistor TR and the light emitting element OL may be further disposed. According to the number of insulation layers disposed between the light emitting element OL and the transistor TR, and an electrical connection method between the light emitting element OL and the transistor TR may be variously changed, and the disclosure is not limited to any one embodiment.

The light emitting element layer DP-OL may include a light emitting element OL and a pixel definition film PDL. The light emitting element OL and the pixel definition film PDL may be disposed on the sixth insulation layer 60. The light emitting element OL may include a first electrode AE, a light emission layer EM, and a second electrode CE.

The first electrode AE may be electrically connected to the second connection electrode CN2 through a contact hole that passes the sixth insulation layer 60. The first electrode AE may be electrically connected to the transistor TR through the first and second connection electrodes CN1 and CN2.

In the pixel definition film PDL, a pixel opening PX-OP that exposes at least a portion of the first electrode AE may be defined. An area of the first electrode AE, which is exposed from the pixel definition film PDL in a plan view, may correspond to a light emission area. The pixel definition film PDL may include an inorganic layer, an organic layer, or a composite material layer. According to an embodiment, the pixel definition film PDL may further include a black pigment or a black dye.

The light emission layer EM may be disposed on the first electrode AE. The light emission layer EM may provide light of a color. The light emission layer EM may be disposed in correspondence to the pixel opening PX-OP defined in a pixel definition film PDL. Multiple light emitting elements OL and multiple pixel openings PX-OP may be provided, and the light emission layers EM of the light emitting elements OL may be disposed in correspondence to the pixel openings PX-OP, respectively, and may be provided in the form of patterns that are spaced apart from each other. However, the disclosure is not limited thereto, and in another embodiment, the light emission layers EM of the light emitting elements OL may be formed as an integral common layer.

The second electrode CE may be disposed on the light emission layer EM and the pixel definition film PDL. The second electrode CE may be provided as a common electrode that is disposed in the pixels PX (see FIG. 4) in common.

The light emitting element OL may further include at least one of a hole control area that is disposed between the first electrode AE and the light emission layer EM and an electron control area that is disposed between the light emission layer EM and the second electrode CE. The hole control area may include at least one of a hole generation layer, a hole transport layer, and an electron blocking layer, and the electron control area may include at least one of an electron generation layer, an electron transport layer, and a hole blocking layer.

The encapsulation layer ECL may be disposed on the light emitting element layer DP-OL. The encapsulation layer ECL may be disposed on the light emitting element OL and the pixel definition film PDL, and may seal the light emitting element OL. The encapsulation layer ECL may include at least one of an inorganic film and an organic film. In an embodiment, the encapsulation layer ECL may include a first inorganic film EN1, a second inorganic film EN3, and an organic film EN2 that is disposed between the first and second inorganic films EN1 and EN3. However, the configuration of the encapsulation layer ECL is not limited thereto as long as it may seal the light emitting element OL.

The first inorganic film EN1 may be disposed on the second electrode CE, and the organic film EN2 and the second inorganic film EN3 may be sequentially disposed on the first inorganic film EN1 in a thickness direction of the display panel DP. The first and second inorganic films EN1 and EN3 may protect the light emitting element OL from moisture or oxygen that is introduced from the outside. For example, each of the first and second inorganic films EN1 and EN3 may include at least one of silicon nitride, silicon oxynitride, silicon oxide, titanium oxide, and aluminum oxide. However, materials of the first and second inorganic films EN1 and EN3 are not limited thereto. The organic film EN2 may prevent foreign substances from flowing into the light emitting element OL, and may cover steps of the components that are disposed under the organic film EN2. For example, the organic film EN2 may include an acrylic organic material. However, the material of organic film EN2 is not limited thereto.

The input sensing unit ISP may be disposed on the display panel DP. The input sensing unit ISP may include a base layer IL1, a first sensing insulation layer IL2, a first sensing conductive layer CL1, and a second sensing conductive layer CL2. The input sensing unit ISP may further include a second sensing insulation layer IL3 (see FIG. 3) as illustrated in FIG. 3. The above description may be applied to the components in the same way.

The base layer IL1 may contact the uppermost layer of the encapsulation layer ECL. For example, the base layer IL1 may contact the second inorganic film EN3 of the encapsulation layer ECL. The base layer IL1 of the input sensing unit ISP may be formed on (e.g., directly on) the base surface provided by the encapsulation layer ECL. However, the disclosure is not limited thereto, and according to another embodiment, the base layer IL1 may be omitted, and the first sensing conductive layer CL1 of the input sensing unit ISP may contact the encapsulation layer ECL.

The first sensing conductive layer CL1 may be disposed on the base layer IL1, and the second sensing conductive layer CL2 may be disposed on the first sensing insulation layer IL2. The first sensing conductive layer CL1 and the second sensing conductive layer CL2 may constitute a sensing electrode TE. The sensing electrode TE may correspond to one of the first and second sensing electrodes TEY (see FIG. 5) described above. For example, the first sensing conductive layer CL1 may include a connection pattern BP of the sensing electrode TE, and the second sensing conductive layer CL2 may include a sensing pattern SP of the sensing electrode TE. However, the disclosure is not limited thereto, and in another embodiment, the first sensing conductive layer CL1 may include a sensing pattern SP, and the second sensing conductive layer CL2 may include a connection pattern BP.

The connection pattern BP may correspond to the first connection pattern BP1 (see FIG. 5) or the second connection pattern BP2 (see FIG. 5), and the sensing pattern SP may correspond to the first sensing pattern SP1 (see FIG. 5) or the second sensing pattern SP2 (see FIG. 5). The connection pattern BP and the sensing pattern SP may be disposed at different layers, and may be connected through a contact hole that passes through the first sensing insulation layer IL2. However, the disclosure is not limited thereto, and in another embodiment the connection pattern BP and the sensing pattern SP may be disposed at a same layer and formed integrally.

The sensing electrode TE may have a mesh-shaped pattern, and may be disposed in correspondence to an area, in which the pixel definition film PDL is disposed. However, the disclosure is not limited thereto, and in another embodiment, the sensing electrode TE may be provided as a pattern of a single shape that overlaps the light emitting element OL in a plan view, and the sensing electrode TE may include a transparent conductive material.

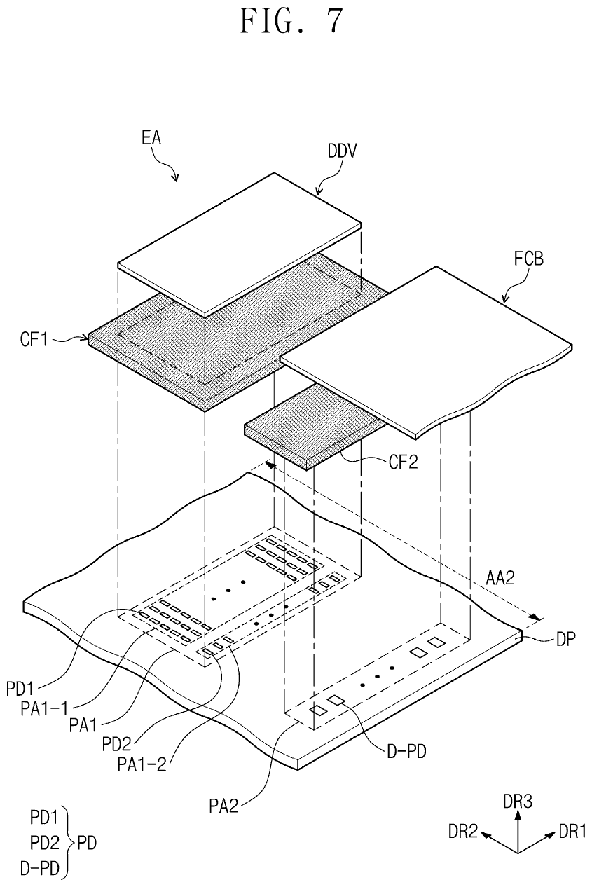

FIG. 7 is a perspective view of an electronic device EA according to an embodiment of the disclosure. FIG. 7 schematically illustrates some components of an electronic device EA, which are disposed in correspondence to the second base area AA2.

The second base area AA2 may correspond to a partial area of a non-display area NDA (see FIG. 4). As illustrated in FIG. 7, an area of the non-display area NDA or the second base area AA2, to which the data driver DDV is bonded, may be defined as a first pad area PA1, and an area, to which the flexible circuit board FCB is bonded, may be defined as a second pad area PA2.

The data driver DDV may be bonded to the first pad area PA1 by a first adhesion layer CF1, and the flexible circuit board FCB may be bonded to the second pad area PA2 by a second adhesion layer CF2. Each of the first and second adhesion layers CF1 and CF2 may include a synthetic resin having adhesive properties. Each of the first and second adhesion layers CF1 and CF2 may be a non-conductive film. For example, each of the first and second adhesion layers CF1 and CF2 may be an adhesive resin that does not include conductive particles.

However, the disclosure is not limited thereto, and in another embodiment, one of the first adhesion layer CF1 and the second adhesion layer CF2 may be omitted. For example, the data driver DDV and the flexible circuit board FCB may be bonded to the first pad area PA1 and the second pad area PA2, respectively, through ultrasonic bonding.

The display panel DP may include multiple pads PD. The pads PD may include first signal pads PD1, second signal pads PD2, and display pads D-PD. The first signal pads PD1, the second signal pads PD2, and the display pads D-PD may be pads that are disposed on a signal transmission path.

The first signal pads PD1 may be input pads that are disposed in correspondence to the output pad of the data driver DDV and receive a signal from the data driver DDV. The second signal pads PD2 may be output pads that are disposed in correspondence to the input pad of the data driver DDV, and output a signal to the data driver DDV. The display pads D-PD may be panel input pads that receive a signal from the flexible circuit board FCB.

Each of the first signal pads PD1 may be electrically connected to the pixels PX (see FIG. 4) of the display panel DP through signal lines, and may transmit and receive signals to and from the pixels PX (see FIG. 4). The second signal pads PD2 may be electrically connected to a corresponding one of the display pads D-PD through signal lines, and the display pads D-PD and the second signal pads PD2 electrically connected to each other may transmit and receive signals.

The first pad area PA1 may include a first sub pad area PA1-1 and a second sub pad area PA1-2. The first sub pad area PA1-1 may be defined as an area, in which the first signal pads PD1 are disposed. The second sub pad area PA1-2 may be defined as an area, in which the second signal pads PD2 are disposed.

The first signal pads PD1 may be arranged in the first direction DR1 and the second direction DR2 in the first sub pad area PA1-1. Those of the first signal pads PD1, which is arranged along the first direction DR1, may be defined as pad rows. FIG. 7 schematically illustrates that five pad rows are arranged along a second direction DR2 according to an embodiment. However, the disclosure is not limited thereto.

The second signal pads PD2 may be arranged in the first direction DR1 in the second sub pad area PA1-2. The second signal pads PD2 may be arranged in one pad row. However, the disposition of the second signal pads PD2 is not limited thereto.

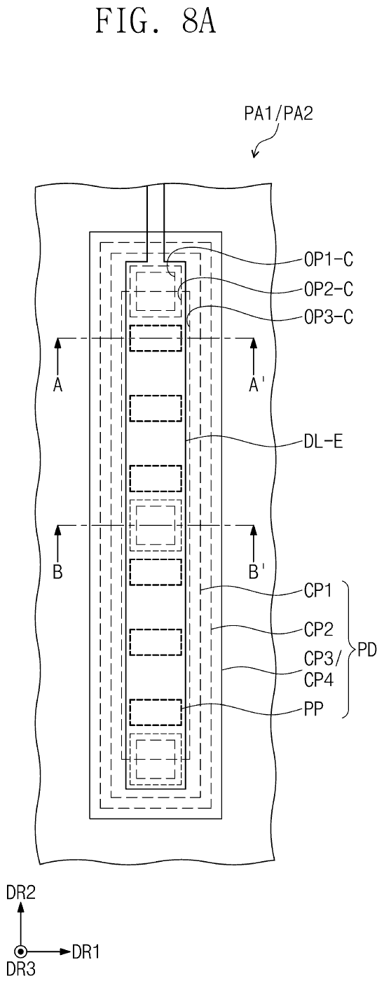

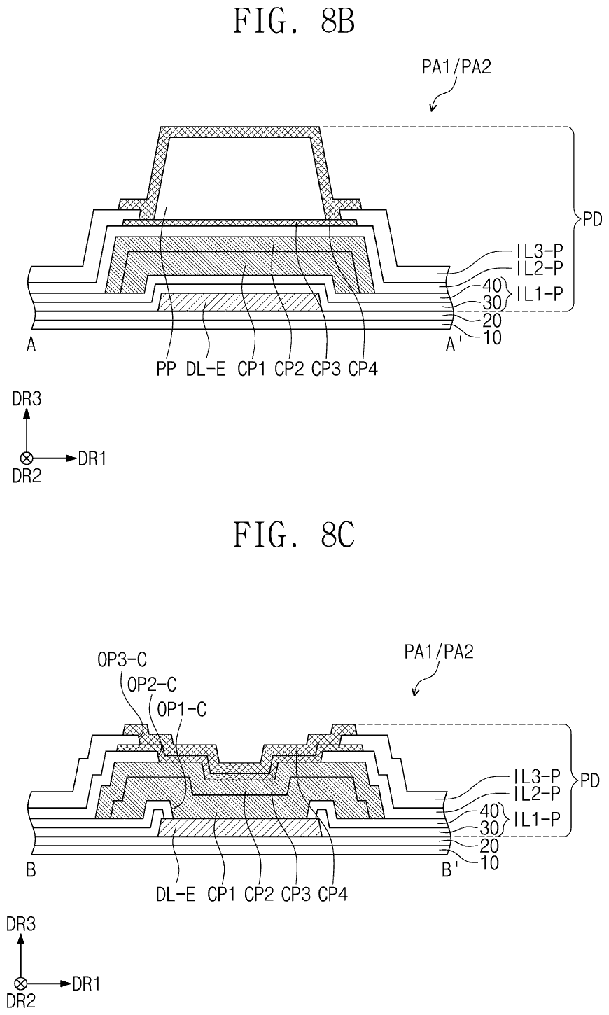

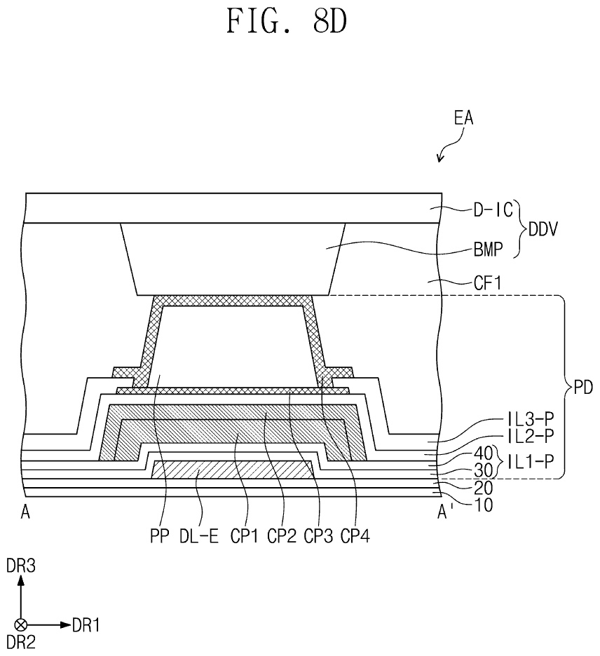

FIG. 8A is a plan view of a pad area PA1/PA2 according to an embodiment of the disclosure. FIGS. 8B and 8C are schematic cross-sectional views of a pad area PA1/PA2 according to an embodiment of the disclosure. FIG. 8D is a schematic cross-sectional view of an electronic device EA according to an embodiment of the disclosure.

FIG. 8A is a schematic plan view of the pad area PA1/PA2 according to an embodiment of the disclosure. FIG. 8B is a schematic cross-sectional view of the pad area PA1/PA2 corresponding to line A-A′ of FIG. 8A, and FIG. 8C is a schematic cross-sectional view of the pad area PA1/PA2 corresponding to line B-B′ of FIG. 8A. FIG. 8D is a schematic cross-sectional view illustrating a bonding structure of the pad area PA1/PA2 of the electronic device EA according to an embodiment of the disclosure. FIG. 8D schematically illustrates a bonding structure of the electronic device EA in the pad area PA1/PA2 corresponding to line A-A′ of FIG. 8A.

The signal pad PD illustrated in FIGS. 8A to 8D may be one of the first signal pad PD1, the second signal pad PD2, and the display pad D-PD described with reference to FIG. 7. Furthermore, data lines DL1 to DLn (see FIG. 4) including a distal end DL-E are illustrated as embodiments of signal lines, but the disclosure is not limited thereto. In another embodiment, the signal lines may be signal lines other than the data lines DL1 to DLn (see FIG. 4).

Hereinafter, the pad area PA1/PA2 will be described, while focusing on the first sub pad area PA1-1 (see FIG. 7), in which the data lines DL1 to DLn (see FIG. 4) are disposed. The description of the first sub pad area PA1-1 (see FIG. 7) may be applied in the same manner to the second sub pad area PA1-2, except that connection signal lines are disposed instead of the data lines DL1 to DLn (see FIG. 4).

Referring to FIGS. 8A to 8C, the signal pad PD may include a first conductive pattern CP1, a second conductive pattern CP2, a third conductive pattern CP3, a fourth conductive pattern CP4, and at least one insulation pattern PP. The signal pad PD may further include a first pad insulation layer IL1-P, a second pad insulation layer IL2-P, and a third pad insulation layer IL3-P, and for convenience of description, FIG. 8A illustrates only the contact holes OP1-C, OP2-C, and OP3-C defined in the pad insulation layers IL1-P, IL2-P, and IL3-P.

A distal end DL-E of the data line may extend in the second direction DR2 in a plan view. For example, the distal end DL-E may have a length or width in the second direction DR2 that is greater than a length or width in the first direction DR1. The distal end DL-E of the data line and the gate electrode GE (see FIG. 6) of the transistor TR (see FIG. 6) disposed in the display area DA (see FIG. 6) described above may be disposed at a same layer. For example, the distal end DL-E of the data line may be disposed on the second insulation layer 20. The distal end DL-E of the data line and the gate electrode GE (see FIG. 6) may include a same material. The distal end DL-E of the data line and the gate electrode GE (see FIG. 6) may be formed in a same processing operation (for example, a patterning operation). A distal end DL-E of the data line and the gate electrode GE (see FIG. 6) may have a same thickness.

However, the position of the distal end DL-E is not limited thereto. In another embodiment, the distal end DL-E and the upper electrode UE illustrated in FIG. 6 may be disposed at a same layer, may include a same material, and may have a same lamination structure. In another embodiment, some of the signal lines and the gate electrode GE (see FIG. 6) may be formed through a same process, and others of the signal lines and the upper electrode UE (see FIG. 6) may be formed through a same process.

The data lines DL1 to DLn (see FIG. 4) may be disposed on a layer and have an integral shape, but the disclosure is not limited thereto. In another embodiment, a data line DL1 to DLn (see FIG. 4) may include multiple portions that are disposed on different layers.

The first conductive pattern CP1 may be disposed on the distal end DL-E of the data line. In a plan view, the first conductive pattern CP1 may overlap the distal end DL-E of the data line. In a plan view, the distal end DL-E of the data line may be disposed inside the first conductive pattern CP1, for example, the first conductive pattern CP1 may completely cover the distal end DL-E of the data line, but the disclosure is not limited thereto.

The first conductive pattern CP1 may be connected to the distal end DL-E of the data line DL1 to DLn (see FIG. 4) through at least one first contact hole OP1-C defined in the first pad insulation layer IL1-P. In the specification, the insulation layers that are disposed between the distal end DL-E and the first conductive pattern CP1 may be defined as the first pad insulation layer IL1-P. In an embodiment, the third and fourth insulation layers 30 and 40 may be defined as the first pad insulation layer IL1-P. The lamination structure of the first pad insulation layer IL1-P may be changed according to the lamination structure of the circuit element layer DP-CL (see FIG. 6). In an embodiment, the first contact hole OP1-C may be defined in a larger number of insulation layers or in a smaller number of insulation layers than the third and fourth insulation layers 30 and 40. The first conductive pattern CP1 and the distal end DL-E may be distinguished by the first pad insulation layers IL1-P (e.g., the third and fourth insulation layers 30 and 40).

In FIG. 8A, a signal pad PD including three first contact holes OP1-C and six insulation patterns PP is illustrated according to an embodiment, but the numbers of the first contact holes OP1-C and the insulation patterns PP are not limited thereto. The first contact holes OP1-C may overlap the distal end DL-E in a plan view. The first contact holes OP1-C may be defined inside the distal end DL-E in a plan view. The first contact holes OP1-C may be defined inside the first conductive pattern CP1 in a plan view. The first contact holes OP1-C may be arranged in the second direction DR2. The first contact holes OP1-C may be spaced apart from each other in the second direction DR2. A portion of the first conductive pattern CP1 may overlap the first contact holes OP1-C in a plan view. A portion of the first conductive pattern CP1, which overlaps the first contact holes OP1-C, may contact the distal end DL-E and electrically connected to each other.

The first conductive pattern CP1 and the first connection electrode CN1 (see FIG. 6) connected to the transistor TR (see FIG. 6) of the display area DA (see FIG. 6) described above may be disposed at a same layer. For example, the first conductive pattern CP1 may be disposed on the fourth insulation layer 40. The first conductive pattern CP1 and the first connection electrode CN1 (see FIG. 6) may include a same material. The first conductive pattern CP1 and the first connection electrode CN1 (see FIG. 6) may be formed in a same process operation. The first conductive pattern CP1 may be a single-layered or multi-layered structure, and the first conductive pattern CP1 and the first connection electrode CN1 (see FIG. 6) may have a same lamination structure. The first conductive pattern CP1 and the first connection electrode CN1 (see FIG. 6) may have a same thickness. A thickness of the first conductive pattern CP1 may be in a range of about 5300 Å to about 8300 Å in the third direction DR3. For example, the thickness of the first conductive pattern CP1 may be in a range of about 6500 Å to about 7100 Å.

The second conductive pattern CP2 may be disposed on the first conductive pattern CP1. The second conductive pattern CP2 and the first conductive pattern CP1 may be distinguished by a boundary line in a cross-sectional view formed as the second conductive pattern CP2 and the first conductive pattern CP1 are formed in different process operations. The second conductive pattern CP2 may contact the first conductive pattern CP1 and electrically connected to the first conductive pattern CP1. In a plan view, the second conductive pattern CP2 may overlap the first conductive pattern CP1. In a plan view, the first conductive pattern CP1 may be disposed inside the second conductive pattern CP2. However, the disclosure is not limited thereto, and in another embodiment, the second conductive pattern CP2 may be disposed inside the first conductive pattern CP1 in a plan view or may be disposed in a same position.

A portion of the second conductive pattern CP2 may be exposed by at least one second contact hole OP2-C defined in the second pad insulation layer IL2-P. The second conductive pattern CP2 may contact and be electrically connected to the third conductive pattern CP3 through the second contact hole OP2-C. The signal pad PD including three second contact holes OP2-C is illustrated in FIG. 8A according to an embodiment, but the number of the second contact holes OP2-C is not limited thereto. In a plan view, the second contact holes OP2-C may be defined in the second conductive pattern CP2. In a plan view, the second contact holes OP2-C may be defined in the third conductive pattern CP3.

The second pad insulation layer IL2-P and the base layer IL1 of the input sensing unit ISP (see FIG. 6) described above may include a same material. The second pad insulation layer IL2-P and the base layer IL1 may be formed in a same process operation. The second pad insulation layer IL2-P may include an inorganic film. For example, the inorganic film may include at least one of aluminum oxide, titanium oxide, silicon nitride, silicon oxide, silicon oxynitride, zirconium oxide, and hafnium oxide.

The second conductive pattern CP2 and the second connection electrode CN2 (see FIG. 6) connected to the first connection electrode CN1 (see FIG. 6) of the display area DA (see FIG. 6) described above may be disposed at a same layer. The second conductive pattern CP2 and the second connection electrode CN2 (see FIG. 6) may include a same material. The second conductive pattern CP2 and the second connection electrode CN2 (see FIG. 6) may be formed in a same process operation. The second conductive pattern CP2 may be a single-layered or multi-layered structure, and the second conductive pattern CP2 and the second connection electrode CN2 (see FIG. 6) may have a same lamination structure. The second conductive pattern CP2 and the second connection electrode CN2 (see FIG. 6) may have a same thickness. A thickness of the second conductive pattern CP2 may be in a range of about 5300 Å to about 8300 Å in the third direction DR3. For example, the thickness of the second conductive pattern CP2 may be in a range of about 6500 Å to about 7100 Å.

The third conductive pattern CP3 may be disposed on the second conductive pattern CP2. In a plan view, the third conductive pattern CP3 may overlap the second conductive pattern CP2. In a plan view, the third conductive pattern CP3 may be disposed inside the second conductive pattern CP2, but the disclosure is not limited thereto, and in another embodiment, the second conductive pattern CP2 may be disposed inside the third conductive pattern CP3 or may be disposed in a same position.

The third conductive pattern CP3 may be connected to the second conductive pattern CP2 through at least one second contact hole OP2-C defined in the second pad insulation layer IL2-P. The second contact hole OP2-C may be disposed inside the third conductive pattern CP3. The second contact hole OP2-C may overlap the first contact hole OP1-C in a plan view. However, the disclosure is not limited thereto. In another embodiment, the first contact hole OP1-C and the second contact hole OP2-C may partially overlap each other or may not overlap each other in a plan view.

The third conductive pattern CP3 and the first sensing conductive layer CL1 of the display area DA (see FIG. 6) described above may include a same material. The third conductive pattern CP3 and the first sensing conductive layer CL1 may be formed in a same process operation. The third conductive pattern CP3 may be a single-layered or multi-layered structure, and the third conductive pattern CP3 and the first sensing conductive layer CL1 may have a same lamination structure. The third conductive pattern CP3 and the first sensing conductive layer CL1 may have a same thickness. A thickness of the third conductive pattern CP3 may be smaller than the thickness of each of the first conductive pattern CP1 and the second conductive pattern CP2. The thickness of the third conductive pattern CP3 may be in a range of about 2000 Å to about 4000 Å in the third direction DR3. For example, the thickness of the third conductive pattern CP3 may be in a range of about 2500 Å to about 3500 Å. Accordingly, when pressed by a bump electrode BMP as illustrated in FIG. 8D, the deformation of the lower surface of the insulation pattern PP may be less than in case that the lower layer of the insulation pattern PP is thicker, and the pressure may be concentrated on an upper surface of the insulation pattern PP.

The fourth conductive pattern CP4 may be disposed on the third conductive pattern CP3. In a plan view, the fourth conductive pattern CP4 may overlap the third conductive pattern CP3. Although FIG. 8A illustrates that the third conductive pattern CP3 and the fourth conductive pattern CP4 completely overlap each other in a plan view for convenience, the disclosure is not limited thereto, and the third conductive pattern CP3 may be disposed inside the fourth conductive pattern CP4, or the fourth conductive pattern CP4 may be disposed inside the third conductive pattern CP3.

The fourth conductive pattern CP4 may be connected to the third conductive pattern CP3 through the third contact hole OP3-C defined in the third pad insulation layer IL3-P. In a plan view, the third contact hole OP3-C may overlap the third conductive pattern CP3. In a plan view, the third contact hole OP3-C may be disposed inside the third conductive pattern CP3. In a plan view, the third contact hole OP3-C may be disposed inside the fourth conductive pattern CP4. In a plan view, the third contact hole OP3-C may overlap the first contact hole OP1-C. In a plan view, the third contact hole OP3-C may overlap the second contact hole OP2-C. In a plan view, the third contact hole OP3-C may overlap the insulation pattern PP. In a plan view, the insulation pattern PP may be disposed inside the third contact hole OP3-C.

The third pad insulation layer IL3-P and the first sensing insulation layer IL2 of the input sensing unit ISP (see FIG. 6) described above may include a same material. The third pad insulation layer IL3-P and the first sensing insulation layer IL2 may be formed in a same process operation. The third pad insulation layer IL3-P may include an organic film. For example, the organic film may include at least one of an acrylic resin, a methacrylic resin, a polyisoprene resin, a vinyl resin, an epoxy resin, a urethane resin, a cellulose resin, a polyimide resin, a polyamide resin, and a perylene resin.

The fourth conductive pattern CP4 and the second sensing conductive layer CL2 of the display area DA (see FIG. 6) described above may include a same material. The fourth conductive pattern CP4 and the second sensing conductive layer CL2 may be formed in a same process operation. The fourth conductive pattern CP4 may have a multi-layered structure, and the fourth conductive pattern CP4 and the second sensing conductive layer CL2 may have a same lamination structure. The fourth conductive pattern CP4 and the second sensing conductive layer CL2 may have a same thickness. A thickness of the fourth conductive pattern CP4 may be thinner than the thickness of the first conductive pattern CP1 and the second conductive pattern CP2. The thickness of the fourth conductive pattern CP4 may be in a range of about 2000 Å to about 4000 Å in the third direction DR3. For example, the thickness of the fourth conductive pattern CP4 may be 2500 Å to 3500 Å.

The fourth conductive pattern CP4 may include a first layer disposed on the third conductive pattern CP3, a second layer disposed on the first layer, and a third layer disposed on the second layer. The thickness of the second layer may be greater than the thicknesses of the first layer and the third layer. The second layer may have a higher conductivity than the first layer and the third layer. The first layer and the third layer may include a same material. The second layer and the first layer and the third layer may include different materials. For example, the first layer and the third layer may include titanium (Ti), and the second layer may include aluminum (Al).

The insulation patterns PP may be disposed between the third conductive pattern CP3 and the fourth conductive pattern CP4. Lower surfaces of the insulation patterns PP may contact the third conductive pattern CP3, and side surfaces and upper surfaces of the insulation patterns PP may be covered by the fourth conductive pattern CP4, respectively. The insulation patterns PP may form protrusions in the pad area PA1/PA2.

In a plan view, the insulation patterns PP may overlap the third conductive pattern CP3 and the fourth conductive pattern CP4, respectively. In a plan view, the insulation patterns PP may be spaced apart from the first contact holes OP1-C. In an embodiment, the insulation patterns PP may be arranged in the second direction DR2. The insulation patterns PP may be spaced apart from each other in the second direction DR2. In a plan view, the insulation patterns PP may be disposed inside the third contact hole OP3-C, and may be spaced apart from the third pad insulation layer IL3-P. The fourth conductive pattern CP4 may be filled between the insulation patterns PP and the third pad insulation layer IL3-P. The fourth conductive pattern CP4 disposed between the insulation patterns PP and the third pad insulation layer IL3-P may contact the third conductive pattern CP3 to be electrically connected to each other.

The insulation patterns PP may be disposed between the adjacent first contact holes OP1-C. In FIG. 8A, three insulation patterns PP disposed on each of two planes between the three first contact holes OP1-C are illustrated according to an embodiment, but the disposition relationship is not limited thereto.

In FIG. 8A, it is illustrated that the insulation patterns PP are rectangular in a plan view according to an embodiment, but the disclosure is not limited thereto. The shapes of the insulation patterns PP in a plan view may be changed to a polygon, a circle, an ellipse, or the like. In another embodiment, the shapes of the insulation patterns PP may not be same in a plan view.

The insulation pattern PP may have a trapezoidal shape in a cross-sectional view. The insulation pattern PP may have an inclined side surface, and an inclination with respect to a lower surface may be an acute angle. However, the disclosure is not limited thereto, and the insulation pattern PP may have a rectangular shape in a cross-sectional view or an inverse trapezoidal shape.

The insulation pattern PP may include a polymer. The insulation pattern PP may include a thermosetting polymer. However, the disclosure is not limited thereto, and in another embodiment, the insulation pattern PP may include a thermoplastic polymer.

In an embodiment, the insulation pattern PP and the first sensing insulation layer IL2 (see FIG. 6) of the input sensing unit ISP may be formed through a same process. Accordingly, an additional process for forming the insulation pattern PP may not be required.

Referring to FIG. 8D, the signal pad PD according to an embodiment of the disclosure may be disposed between the third conductive pattern CP3 and the fourth conductive pattern CP4 that are patterned in a same process operation as the first sensing conductive layer CL1 and the second sensing conductive layer CL2 of the input sensing unit ISP (see FIG. 6). Accordingly, compared to the case, in which the insulation pattern PP is disposed between the first conductive pattern CP1 and the second conductive pattern CP2, an extent of the signal pad PD that contacts the bump electrode BMP may be reduced, and thus, a pressure applied to the contact surface per unit area may be increased, and thus, a bonding reliability in a low-pressure process may be improved. For example, while an upper layer (e.g., a third layer) of the fourth conductive pattern CP4 of the signal pad PD, which contacts the bump electrode BMP, may be stretched by a pressure to form a groove, a second layer (e.g., an aluminum layer) having a high conductivity may be exposed, and a second layer may be electrically connected while contacting the bump electrode BMP. Furthermore, in case that the insulation pattern PP is disposed between the second conductive pattern CP2 and the third conductive pattern CP3, the second conductive pattern CP2 disposed under the insulation pattern PP may be deformed downward by a pressure, and thus, a pressure applied to the signal pad PD that contacts the bump electrode BMP may be reduced. The third conductive pattern CP3 may be disposed on the second pad insulation layer IL2-P, and the second pad insulation layer IL2-P may include an inorganic film to support the third conductive pattern CP3, and the third conductive pattern CP3 may be formed to have a smaller thickness than the first and second conductive patterns CP1 and CP2, and thus, the third conductive pattern CP3 may be less deformed by a pressure. In the case of the signal pad PD according to an embodiment of the disclosure, deformation of the third conductive pattern CP3 disposed under the insulation pattern PP may be minimized, and a pressure may be concentrated on a contact surface of the signal pad PD, which contacts the bump electrode BMP, and thus, a bonding reliability in a low pressure process may be improved. The data driver DDV may include a circuit board D-IC and the bump electrode BMP disposed on the circuit board D-IC.

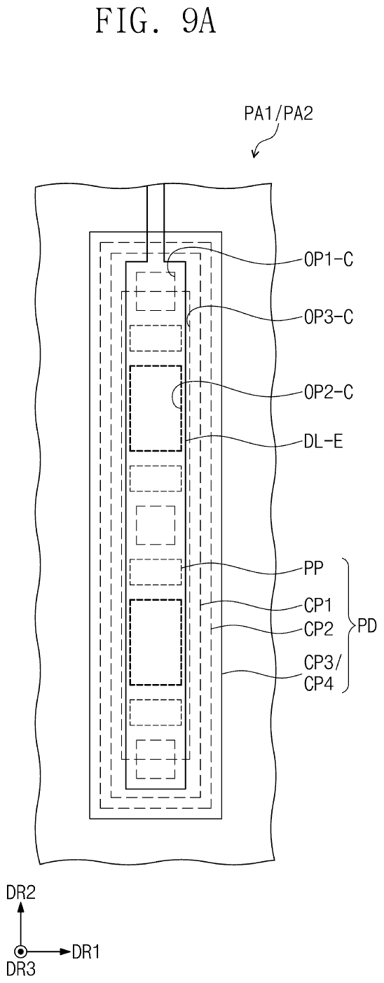

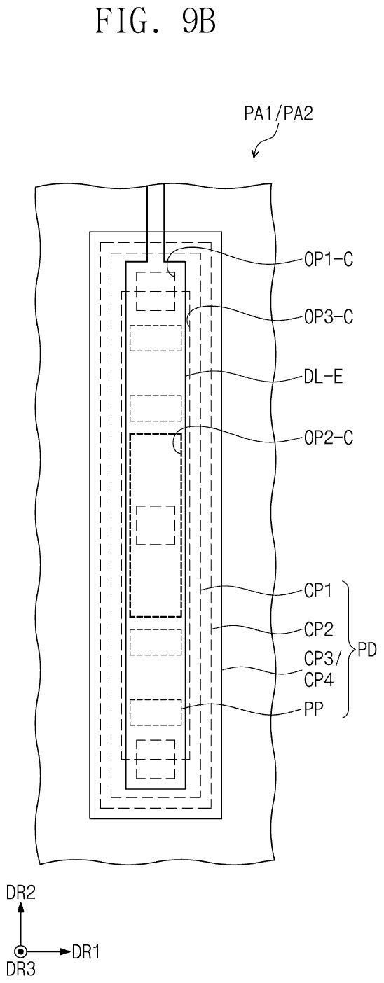

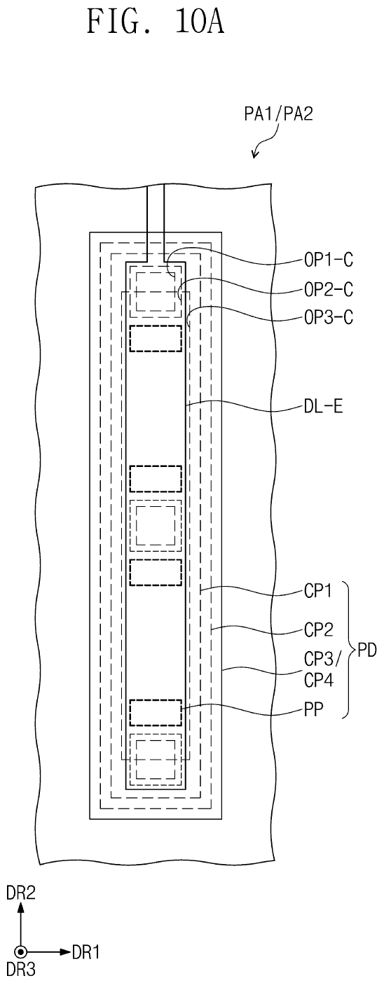

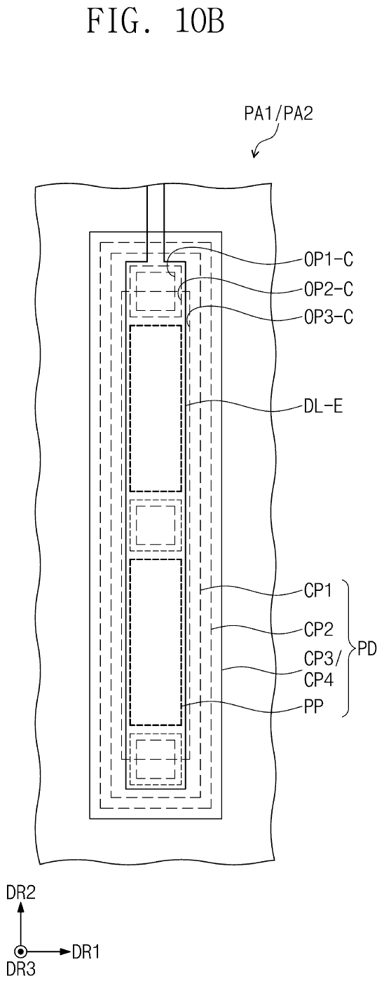

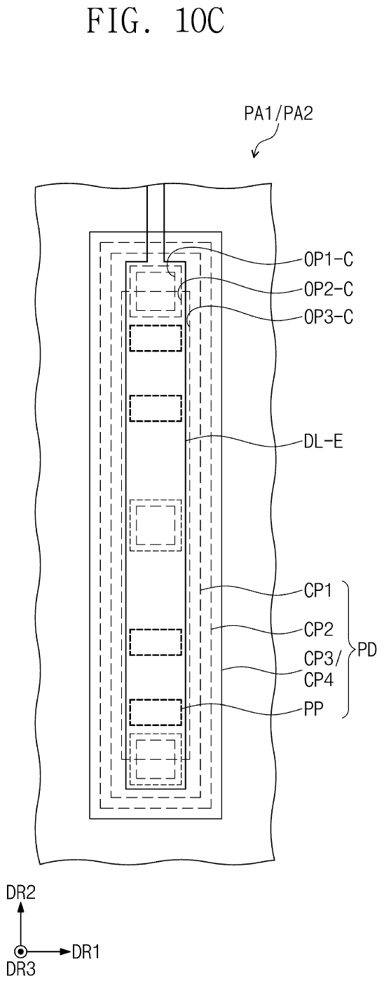

FIGS. 9A to 10C are plan views of a pad area PA1/PA2 according to an embodiment of the disclosure, respectively. The descriptions made with reference to FIGS. 8A to 8D may be applied to FIGS. 9A to 10C in the same way.

FIGS. 9A and 9B are plan views illustrating embodiments, in which the number, disposition, or size of the second contact holes OP2-C are different from those of FIG. 8A, respectively. The number and disposition of the insulation pattern PP may be changed according to the disposition of the second contact holes OP2-C.

Referring to FIG. 9A, the second contact hole OP2-C defined in the second pad insulation layer IL2-P in a plan view may not overlap the first contact hole OP1-C defined in the first pad insulation layer IL1-P. Furthermore, in a plan view, the second contact hole OP2-C may not overlap the insulation patterns PP. For example, in a plan view, the second contact hole OP2-C may be disposed between two adjacent insulation patterns PP. The number of second contact holes OP2-C that are defined in one signal pad PD may be different from the number of the first contact holes OP1-C. For example, in one signal pad PD, two second contact holes OP2-C may be defined.

Referring to FIG. 9B, in a plan view, the second contact hole OP2-C defined in the second pad insulation layer IL2-P may overlap some of the first contact holes OP1-C defined in the first pad insulation layer IL1-P, and may not overlap some of the first contact holes OP1-C defined in the first pad insulation layer IL1-P. In a plan view, the second contact hole OP2-C may not overlap the insulation patterns PP. In one signal pad PD, one second contact hole OP2-C may be defined.

FIGS. 10A to 10C are plan views illustrating embodiments, in which the number, disposition, or planar shapes of the encapsulation patterns PP are different from those of FIG. 8A, respectively.

Referring to FIGS. 10A and 10C, the number of the insulation patterns PP may be four. In a plan view, the intervals between the insulation patterns PP may be different from each other. Referring to FIG. 10B, in a plan view, the shape of the insulation pattern PP may be a rectangle having a length in the second direction DR2, which is greater than a length in the first direction DR1. In FIGS. 10A to 10C, the insulation patterns PP may not overlap the first contact hole OP1-C and the second contact hole OP2-C.

According to the above description, the display panel and the display module according to the disclosure may have an excellent bonding reliability with an electronic component.

The electronic device according to the disclosure may have an excellent reliability.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display panel comprising:
a display area including a pixel; and
a non-display area including a pad area, and being adjacent to the display area, wherein
a signal pad connected to the pixel through a signal line is disposed in the pad area, and
the signal pad includes:
a first pad insulation layer disposed on a distal end of the signal line, and including a first contact hole exposing a portion of the distal end of the signal line;
a first conductive pattern disposed on the first pad insulation layer, and connected to the distal end of the signal line through the first contact hole;
a second conductive pattern disposed on the first conductive pattern;
a second pad insulation layer disposed on the second conductive pattern, and including a second contact hole exposing a portion of the second conductive pattern;
a third conductive pattern disposed on the second pad insulation layer, and connected to the second conductive pattern through the second contact hole;
a third pad insulation layer disposed on the third conductive pattern, and including a third contact hole exposing a portion of the third conductive pattern;
a fourth conductive pattern disposed on the third pad insulation layer, and connected to the third conductive pattern through the third contact hole; and
at least one insulation pattern disposed between the third conductive pattern and the fourth conductive pattern.

2. The display panel of claim 1, wherein
the display area includes a base layer, a circuit element layer disposed on the base layer, and a light emitting element layer including a light emitting element and disposed on the circuit element layer,
the circuit element layer includes:
a transistor;
a first connection electrode connected to the transistor; and
a second connection electrode connected to the first connection electrode and the light emitting element,
the first conductive pattern and the first connection electrode are disposed at a same layer, and
the conductive pattern and the second connection electrode are disposed at a same layer.

3. The display panel of claim 2, wherein
the transistor includes a semiconductor pattern including a channel, a source, and a drain, and a gate electrode, the gate electrode and the transistor being disposed at different layers, and
the first connection electrode is connected to the source or the drain.

4. The display panel of claim 2, wherein
the light emitting element includes a first electrode, a light emission layer disposed on the first electrode, and a second electrode disposed on the light emission layer, and
the second connection electrode is connected to the first electrode.

5. The display panel of claim 2, wherein
the first conductive pattern and the first connection electrode are formed in a same process operation, and
the second conductive pattern and the second connection electrode are formed in a same process operation.

6. The display panel of claim 1, wherein the insulation pattern includes a polymer.

7. The display panel of claim 1, wherein in a plan view, the insulation pattern is disposed inside the third contact hole.

8. The display panel of claim 1, wherein in a plan view, the insulation pattern is spaced apart from the first contact hole.

9. The display panel of claim 1, wherein
the fourth conductive pattern includes a first layer, a second layer disposed on the first layer, and a third layer disposed on the second layer,
the first layer and the third layer include titanium (Ti), and
the second layer includes aluminum (Al).

10. The display panel of claim 1, wherein
the non-display area includes a first area adjacent to the display area, a second area spaced apart from the first area, and a bending area disposed between the first area and the second area, and
the second area includes the pad area.

11. A display module comprising:
a display panel including a display area including a pixel, and a non-display area including a pad area, in which a signal pad connected to the pixel through a signal line is disposed, and being adjacent to the display area; and
an input sensing part including a first sensing conductive layer disposed on the display panel, a first sensing insulation layer disposed on the first sensing conductive layer, and a second sensing conductive layer disposed on the first sensing insulation layer, wherein
the signal pad includes:
a first conductive pattern connected to a distal end of the signal line;
a second conductive pattern disposed on the first conductive pattern;
a third conductive pattern disposed on the second conductive pattern;
a fourth conductive pattern disposed on the third conductive pattern; and
at least one insulation pattern disposed between the third conductive pattern and the fourth conductive pattern,
the third conductive pattern and the first sensing conductive layer include a same material, and
the fourth conductive pattern and the second sensing conductive layer include a same material.

12. The display module of claim 11, wherein
a thickness of the third conductive pattern and a thickness of the first sensing conductive layer are same, and
a thickness of the fourth conductive pattern and a thickness of the second sensing conductive layer are same.

13. The display module of claim 11, wherein
the third conductive pattern and the first sensing conductive layer are formed in a same process operation, and
the fourth conductive pattern and the second sensing conductive layer are formed in a same process operation.

14. The display module of claim 11, wherein
the fourth conductive pattern includes a first layer, a second layer disposed on the first layer, and a third layer disposed on the second layer,
the first layer and the third layer include titanium (Ti), and
the second layer includes aluminum (Al).

15. The display module of claim 11, wherein
the signal pad further includes:
a first pad insulation layer disposed on the distal end of the signal line, and including a first contact hole exposing a portion of the distal end of the signal line;
a second pad insulation layer disposed on the second conductive pattern, and including a second contact hole exposing a portion of the second conductive pattern; and
a third pad insulation layer disposed on the third conductive pattern, and including a third contact hole exposing a portion of the third conductive pattern,
the first conductive pattern is disposed on the first pad insulation layer, and is connected to the distal end of the signal line through the first contact hole,
the third conductive pattern is disposed on the second pad insulation layer, and is connected to the second conductive pattern through the second contact hole, and
the fourth conductive pattern is disposed on the third pad insulation layer, and is connected to the third conductive pattern through the third contact hole.

16. The display module of claim 11, wherein
the display area includes a base layer, a circuit element layer disposed on the base layer, and a light emitting element layer including a light emitting element and disposed on the circuit element layer,
the circuit element layer includes:
a transistor;
a first connection electrode connected to the transistor; and
a second connection electrode connected to the first connection electrode and the light emitting element,
the first conductive pattern and the first connection electrode are disposed at a same layer, and
the second conductive pattern and the second connection electrode are disposed at a same layer.

17. The display module of claim 16, wherein
the first conductive pattern and the first connection electrode are formed in a same process operation, and
the second conductive pattern and the second connection electrode are formed in a same process operation.

18. The display module of claim 11, wherein the insulation pattern includes a polymer.

19. The display module of claim 11, wherein at least one of the first sensing conductive layer and the second sensing conductive layer includes a mesh opening.

20. An electronic device comprising:
a display module including a display panel including a display area including a pixel and a non-display area including a pad area and being adjacent to the display area, and an input sensing part disposed on the display panel;
an electronic component including a bump electrode, and disposed in the pad area; and
an adhesion layer that adheres the display panel and the electronic component, wherein
a signal pad connected to the pixel through a signal line is disposed in the pad area,
the input sensing part includes a first sensing conductive layer disposed on the display panel, a first sensing insulation layer disposed on the first sensing conductive layer, and a second sensing conductive layer disposed on the first sensing insulation layer,
the signal pad includes:
a first conductive pattern connected to a distal end of the signal line;
a second conductive pattern disposed on the first conductive pattern;
a third conductive pattern disposed on the second conductive pattern;
a fourth conductive pattern disposed on the third conductive pattern; and
at least one insulation pattern overlapping the bump electrode in a plan view, and disposed between the third conductive pattern and the fourth conductive pattern,
the third conductive pattern and the first sensing conductive layer include a same material, and
the fourth conductive pattern and the second sensing conductive layer include a same material.
